(19) United States
(12) Patent Application Publication
(10) Pub. No.: US 2024/0203655 A1
(43) Pub. Date: Jun. 20, 2024

(54) EQUIVALENT CIRCUIT MODEL CREATION METHOD FOR MULTI-TERMINAL CAPACITORS, NON-TRANSITORY COMPUTER-READABLE MEDIUM INCLUDING EQUIVALENT CIRCUIT MODEL CREATION PROGRAM, SIMULATION METHOD, AND SIMULATION DEVICE

(71) Applicant: Murata Manufacturing Co., Ltd., Nagaokakyo-shi (JP)

(72) Inventors: Seiji HIDAKA, Nagaokakyo-shi (JP); Atsutaka MORI, Nagaokakyo-shi (JP); Yukihiro FUJITA, Nagaokakyo-shi (JP)

(21) Appl. No.: 18/586,825

(22) Filed: Feb. 26, 2024

Related U.S. Application Data
(63) Continuation of application No. PCT/JP2022/031766, filed on Aug. 23, 2022.

(30) Foreign Application Priority Data
Sep. 6, 2021 (JP) 2021-145013

(51) Int. Cl. H01G 4/232; G06F 30/3323; H01G 4/30

(52) U.S. Cl. CPC H01G 4/232; G06F 30/3323; H01G 4/30

(57) ABSTRACT

A method for creating an equivalent circuit model of a multi-terminal capacitor including staggered positive and negative outer electrode terminals includes measuring S parameters of the multi-terminal capacitor, deriving a total impedance of the multi-terminal capacitor based on measured S parameter measurement values, creating a two-terminal equivalent circuit model from the derived total impedance of the multi-terminal capacitor, deriving a unit-cell equivalent circuit model from the created two-terminal equivalent circuit model, creating a three-dimensional grid topology by combining the derived unit-cell equivalent circuit model and an equivalent circuit model of a parasitic component including capacitive and inductive circuit elements, and setting terminals of the multi-terminal capacitor at nodes in the created three-dimensional grid topology.

### CROSS REFERENCE TO RELATED APPLICATIONS

This application claims the benefit of priority to Japanese Patent Application No. 2021-145013 filed on Sep. 6, 2021 and is a Continuation Application of PCT Application No. PCT/JP2022/031766 filed on Aug. 23, 2022. The entire contents of each application are hereby incorporated herein by reference.

### BACKGROUND OF THE INVENTION

### 1. Field of the Invention

The present disclosure relates to equivalent circuit model creation methods for multi-terminal capacitors, non-transitory computer-readable media including equivalent circuit model creation programs, simulation methods, and simulation devices.

### 2. Description of the Related Art

A method for deriving equivalent circuit models of capacitors is disclosed in Japanese Unexamined Patent Application Publication No. 2002-259482. The method disclosed in Japanese Unexamined Patent Application Publication No. 2002-259482 targets two-terminal capacitors. More specifically, the method disclosed in Japanese Unexamined Patent Application Publication No. 2002-259482 has been developed for the purpose of deriving equivalent circuit models of two-terminal capacitors.

The method disclosed in Japanese Unexamined Patent Application Publication No. 2002-259482 is unable to derive equivalent circuit models for capacitors with more than two terminals, that is, with three or more terminals.

### SUMMARY OF THE INVENTION

Example embodiments of the present invention provide equivalent circuit model creation methods, non-transitory computer-readable media including equivalent circuit model creation programs, simulation methods, and simulation devices that each enable derivation of equivalent circuit models for multi-terminal capacitors including three or more terminals.

According to an example embodiment of the present invention, an equivalent circuit model creation method is provided for creating an equivalent circuit model of a multi-terminal capacitor including positive and negative outer electrode terminals arranged in a staggered manner such that adjacent terminals among the positive and negative outer electrode terminals have different polarities. The equivalent circuit model creation method includes measuring scattering parameters (S parameters) of the multi-terminal capacitor, deriving a total impedance of the multi-terminal capacitor based on S parameter measurement values measured in the measuring the scattering parameters, creating a two-terminal equivalent circuit model from the total impedance of the multi-terminal capacitor derived in the deriving the total impedance, deriving a unit-cell equivalent circuit model from the two-terminal equivalent circuit model created in the creating the two-terminal equivalent circuit model, creating a three-dimensional grid topology by combining the unit-cell equivalent circuit model derived in the deriving the unit-cell equivalent circuit model and an equivalent circuit model of a parasitic component including capacitive and inductive circuit elements, and setting terminals of the multi-terminal capacitor at nodes in the three-dimensional grid topology created in the creating the three-dimensional grid topology.

According to an example embodiment of the present invention, a non-transitory computer-readable medium including an equivalent circuit model creation program is provided for creating an equivalent t circuit model of a multi-terminal capacitor including positive and negative outer electrode terminals arranged in a staggered manner such that adjacent terminals among the positive and negative outer electrode terminals have different polarities. The equivalent circuit model creation program causes a computer to execute a process including measuring scattering parameters (S parameters) of the multi-terminal capacitor, deriving a total impedance of the multi-terminal capacitor based on S parameter measurement values measured in the measuring the scattering parameters, creating a two-terminal equivalent circuit model from the total impedance of the multi-terminal capacitor derived in the deriving the total impedance, deriving a unit-cell equivalent circuit model from the two-terminal equivalent circuit model created in the creating the two-terminal equivalent circuit model, creating a three-dimensional grid topology by combining the unit-cell equivalent circuit model derived in the deriving the unit-cell equivalent circuit model and an equivalent circuit model of a parasitic component including capacitive and inductive circuit elements, and setting terminals of the multi-terminal capacitor at nodes in the three-dimensional grid topology created in the creating the three-dimensional grid topology.

According to an example embodiment of the present invention, a simulation method is provided for calculating characteristics of a multi-terminal capacitor or characteristics of a circuit including a multi-terminal capacitor by using an equivalent circuit model of the multi-terminal capacitor created through an equivalent circuit model creation method according to an example embodiment of the present invention.

According to an example embodiment of the present invention, a simulation device is provided for calculating characteristics of a multi-terminal capacitor or characteristics of a circuit including the multi-terminal capacitor by using an equivalent circuit model of the multi-terminal capacitor created through an equivalent circuit model creation method according to an example embodiment of the present invention.

According to example embodiments of the present invention, equivalent circuit models of capacitors including three or more terminals are able to be derived.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a flowchart illustrating an equivalent circuit model creation method for multi-terminal capacitors according to an example embodiment of the present invention.

FIG. 2 is a plan view of an exemplary structure of a multi-terminal capacitor.

FIG. 3 illustrates a section of a portion in FIG. 2.

FIG. 4 illustrates a section of a portion in FIG. 2.

FIG. 5 illustrates an internal structure of the multi-terminal capacitor.

FIG. 6 describes a method for measuring S parameters of a multi-terminal capacitor.

FIG. 7 illustrates a section of a portion in FIG. 6.

FIG. 8 illustrates a section of a portion in FIG. 6.

FIG. 9 illustrates an equivalent circuit of a substrate including the multi-terminal capacitor.

FIG. 10 illustrates a base configuration of an equivalent circuit.

FIG. 11 illustrates an equivalent circuit for fitting across lower frequencies.

FIG. 12 illustrates an equivalent circuit for fitting across an entire frequency range including lower frequencies.

FIG. 13 is a table tabulating values of the elements included in the circuits illustrated in FIGS. 10 to 12.

FIG. 14 illustrates an example of impedance changes with respect to frequency.

FIG. 15 illustrates an example of equivalent series resistance changes with respect to frequency.

FIG. 16 is a flowchart illustrating an example of a fitting process.

FIG. 17 illustrates an example of measurement values and simulation values of impedance and equivalent series resistance.

FIG. 18 illustrates an example of measurement values and simulation values of impedance and equivalent series resistance.

FIG. 19 illustrates an example of measurement values and simulation values of impedance and equivalent series resistance.

FIG. 20 illustrates an exemplary unit cell.

FIG. 21 illustrates an image of total impedance.

FIG. 22 illustrates an exemplary array of unit cells that corresponds to the total impedance.

FIG. 23 illustrates weighting coefficients that correspond to specific locations.

FIG. 24 is a table indicating weighting coefficients for individual symbols.

FIG. 25 is a table indicating the count of elements corresponding to each symbol.

FIG. 26 illustrates the definition of an extension coefficient.

FIG. 27 is a table indicating exemplary weighting coefficients for the individual symbols.

FIG. 28 illustrates the relationship between the extension coefficient and the weighting coefficients.

FIG. 29 is a table indicating the relationship between the extension coefficient and the weighting coefficients.

FIG. 30 illustrates elements that implement the impedances of unit cells.

FIG. 31 illustrates an exemplary model of a unit cell.

FIG. 32 illustrates a one-dimensional model that corresponds to the impedance in FIG. 31.

FIG. 33 illustrates a two-dimensional model that corresponds to the one-dimensional model in FIG. 32.

FIG. 34 illustrates a two-dimensional model that is a simplified representation of the two-dimensional model illustrated in FIG. 33.

FIG. 35 illustrates a three-dimensional model constructed by repeatedly combining the simply represented two-dimensional model illustrated in FIG. 34.

FIG. 36 illustrates an exemplary three-dimensional model constructed by repeatedly combining the simply represented two-dimensional model illustrated in FIG. 34.

FIG. 37 illustrates an exemplary three-dimensional model with twelve terminals arranged in three rows and four columns.

FIG. 38 illustrates the exemplary three-dimensional model with twelve terminals arranged in three rows and four columns.

FIG. 39 illustrates the exemplary three-dimensional model with twelve terminals arranged in three rows and four columns.

FIG. 40 illustrates the exemplary three-dimensional model with twelve terminals arranged in three rows and four columns.

FIG. 41 illustrates a procedure for converting a three-dimensional model into circuit diagram symbols.

FIG. 42 illustrates the procedure for converting a three-dimensional model into circuit diagram symbols.

FIG. 43 illustrates the procedure for converting a three-dimensional model into circuit diagram symbols.

FIG. 44 illustrates an exemplary three-dimensional model with a terminal arrangement in three rows and three columns.

FIG. 45 illustrates an exemplary component model visualized using the symbols illustrated in FIG. 43.

FIG. 46 illustrates a multi-terminal capacitor with a terminal arrangement in three rows and five columns.

FIG. 47 illustrates an equivalent circuit of the substrate having the multi-terminal capacitor described with reference to FIG. 6.

FIG. 48 illustrates an exemplary simulation result regarding S parameters.

FIG. 49 illustrates an example of simulation in the time domain.

FIG. 50 illustrates the change in current from a current supply in FIG. 49.

FIG. 51 illustrates examples of the change in load voltage.

FIG. 52 illustrates an exemplary configuration of a simulation device of the present disclosure.

### DETAILED DESCRIPTION OF THE EXAMPLE EMBODIMENTS

Hereinafter, example embodiments of the present invention will be described in detail with reference to the drawings. In the following descriptions of the example embodiments, elements and features the same as or corresponding to those in other example embodiments are denoted by the same reference numerals, and descriptions of these configuration elements will be simplified or omitted. The present invention is not limited by the example embodiments. The elements and features in the example embodiments include elements that are easily replaceable by those skilled in the art or that are the same or substantially the same. The configuration elements described below can be combined in any appropriate manner. Further, each configuration element can be removed, replaced, or changed without departing from the scope and spirit of the present invention.

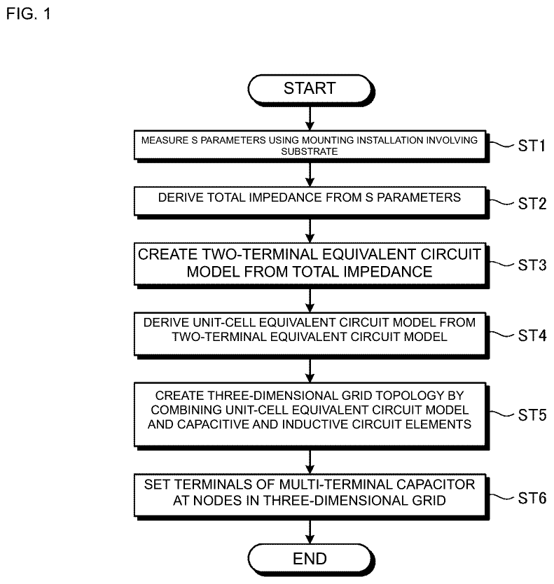

FIG. 1 is a flowchart illustrating an equivalent circuit model creation method for multi-terminal capacitors according to an example embodiment of the present invention. As illustrated in FIG. 1, firstly, a multi-terminal capacitor is formed with a substrate, and scattering parameters (S parameters) of the multi-terminal capacitor are measured (step ST1). For example, a jig including the capacitor can be prepared and used to measure S parameters.

Next, the total impedance of the multi-terminal capacitor is calculated based on the S parameters measured in step ST1 (step ST2). Subsequently, a two-terminal equivalent circuit model is created from the total impedance calculated in step ST2 (step ST3). At this time, the two-terminal equivalent circuit model is created through a fitting process. The fitting process will be described later.

A unit-cell equivalent circuit model is derived from the two-terminal equivalent circuit model created in step ST3 (step ST4). At this time, the unit-cell equivalent circuit model is derived from the two-terminal equivalent circuit model to form a specific periodic structure.

Next, a three-dimensional grid topology is created by combining the unit-cell equivalent circuit model derived in step ST4 and an equivalent circuit model of the parasitic component consisting of capacitive and inductive circuit elements (step ST5). Subsequently, the terminals of the multi-terminal capacitor are set at the nodes in the three-dimensional grid created in step ST5 (step ST6).

### Exemplary Structure of Multi-Terminal Capacitor

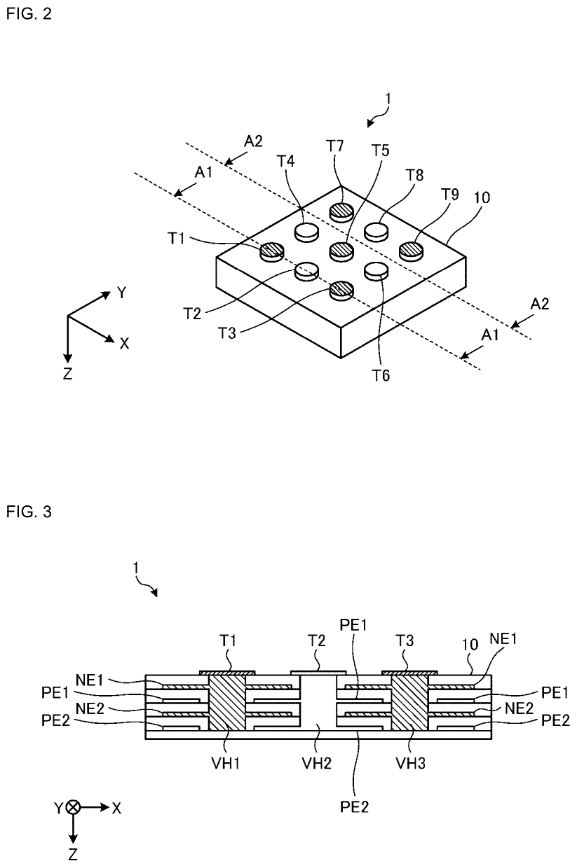

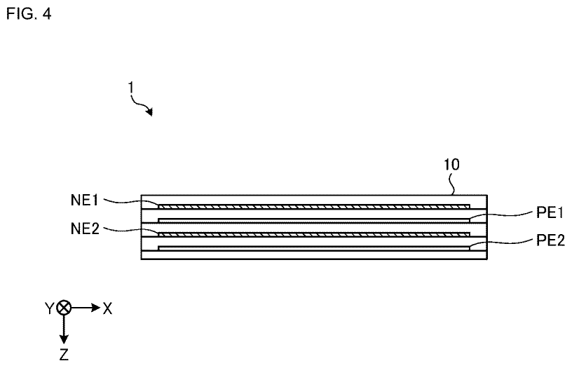

FIGS. 2 to 5 illustrate an exemplary structure of a multi-terminal capacitor. FIG. 2 is a plan view of the exemplary structure of a multi-terminal capacitor. FIG. 3 illustrates a section taken along line A1-A1 in FIG. 2. FIG. 4 illustrates a section taken along line A2-A2 in FIG. 2.

Here, for ease of description, the X-axis direction, the Y-axis direction, and the Z-axis direction, which are orthogonal or substantially orthogonal to each other, are established. The X-axis direction is defined as the direction from a terminal T1 to a terminal T2. The Y-axis direction is defined as the direction from the terminal T1 to a terminal T4. The Z-axis direction is defined as the depth direction of a substrate 10.

As illustrated in FIG. 2, a multi-terminal capacitor 1 of this example is formed with the substrate 10. The multi-terminal capacitor 1 of this example includes nine terminals T1 to T9. In FIG. 2, the terminals T2, T4, T6, and T8 are positive terminals coupled to positive electrodes as described later. The terminals T1, T3, T5, T7, and T9 are negative terminals coupled to negative electrodes as described later. In the multi-terminal capacitor 1 of this example, adjacent terminals in the X-axis direction differ from each other with respect to polarity, and adjacent terminals in the Y-axis direction differ from each other with respect to polarity. For example, referring to the terminal T1, which is a negative terminal, the terminal T2, adjacent to the terminal T1 in the X-axis direction, is a positive terminal, and the terminal T4, adjacent to the terminal T1 in the Y-axis direction, is a positive terminal. Referring to the terminal T4, which is a positive terminal, the terminal T5, adjacent to the terminal T4 in the X-axis direction, is a negative terminal, and the terminals T1 and T7, adjacent to the terminal T4 in the Y-axis direction, are negative terminals. Referring to the terminal T5, which is a negative terminal, the terminals T4 and T6, adjacent to the terminal T5 in the X-axis direction, are positive terminals, and the terminals T2 and T8, adjacent to the terminal T5 in the Y-axis direction, are positive terminals. As described above, adjacent terminals in the X-axis direction differ from each other with respect to polarity, and adjacent terminals in the Y-axis direction differ from each other with respect to polarity. The positive and negative terminals are alternately arranged, or are arranged in a staggered manner, in both the X-axis and Y-axis directions.

FIG. 3 illustrates a section taken along line A1-A1 in FIG. 2. Referring to FIG. 3, the terminal T1 is electrically coupled to negative electrodes NE1 and NE2 inside the substrate 10 by a via-hole VH1 inside the substrate 10. The terminal T2 is electrically coupled to positive electrodes PE1 and PE2 inside the substrate 10 by a via-hole VH2 inside the substrate 10. The terminal T3 is electrically coupled to the negative electrodes NE1 and NE2 inside the substrate 10 by a via-hole VH3 inside the substrate 10.

FIG. 4 illustrates a section taken along line A2-A2 in FIG. 2. Referring to FIG. 4, the negative electrode NE1, the positive electrode PE1, the negative electrode NE2, and the positive electrode PE2 are layered inside the substrate 10. The positive electrode PE1 is isolated from the negative electrodes NE1 and NE2. The positive electrode PE2 is isolated from the negative electrodes NE1 and NE2.

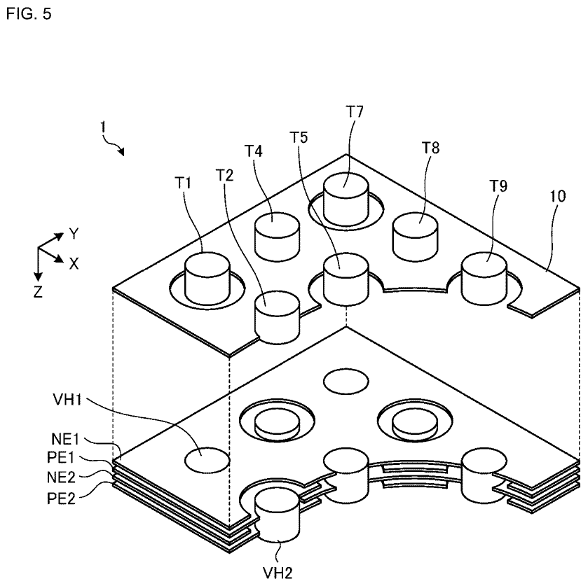

FIG. 5 illustrates an internal structure of the multi-terminal capacitor 1. FIG. 5 illustrates the internal structure of the multi-terminal capacitor 1 in the state in which the surface layer portion of the substrate 10 is separated from the negative electrode NE1. FIG. 5 also illustrates the internal structure of the multi-terminal capacitor 1 with a portion cut away. In FIG. 5, the diameters of holes are illustrated with exaggeration. In FIG. 5, the diameters of the terminals T1 to T5 and T7 to T9 are illustrated as being the same or substantially the same as the diameters of the via-holes VH1 and VH2. However, as illustrated in FIGS. 2 and 3, the actual diameters of the terminals T1 to T5 and T7 to T9 differ from the diameters of the via-holes VH1 and VH2.

As illustrated in FIG. 5, the terminal T1 is electrically coupled to the negative electrode NE1 by the via-hole VH1. The terminal T1 is electrically coupled to the negative electrode NE2 by the via-hole VH1. Similarly, the terminals T5 and T9 are electrically coupled to the negative electrodes NE1 and NE2. The terminal T2 is coupled to the positive electrodes PE1 and PE2 by the via-hole VH2. The other terminals are electrically coupled to the positive electrodes PE1 and PE2, or to the negative electrodes NE1 and NE2 in the same manner. The negative electrode NE1 is positioned facing the positive electrode PE1 with an insulating layer interposed between the negative electrode NE1 and the positive electrode PE1. The insulating layer is not illustrated in FIG. 5. The positive electrode PE1 is positioned facing the negative electrode NE2 with an insulating layer interposed between the positive electrode PE1 and the negative electrode NE2. The insulating layer is not illustrated in FIG. 5. The negative electrode NE2 is positioned facing the positive electrode PE2 with an insulating layer interposed between the negative electrode NE2 and the positive electrode PE2. The insulating layer is not illustrated in FIG. 5. These facing electrodes can provide desired capacitances.

FIGS. 2 to 5 illustrate an exemplary multi-terminal capacitor, defined by a multilayer ceramic capacitor, with the positive and negative terminals arranged in a staggered manner. Any multi-terminal capacitor, such as a silicon capacitor, for example, may be used, provided that the multi-terminal capacitor has positive and negative terminals arranged in a staggered manner.

### Measurement of S Parameters

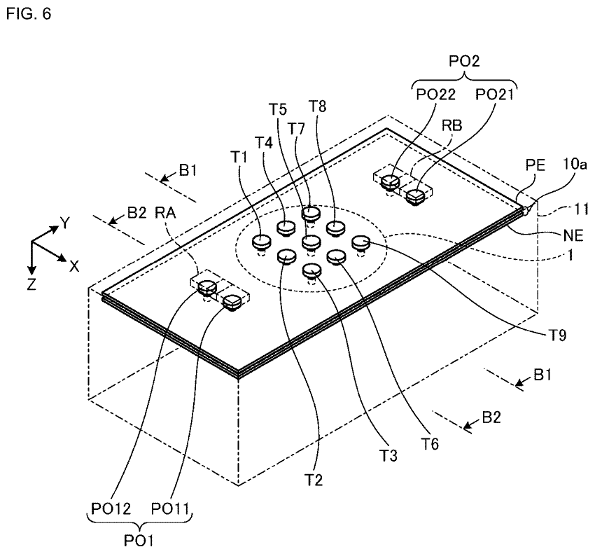

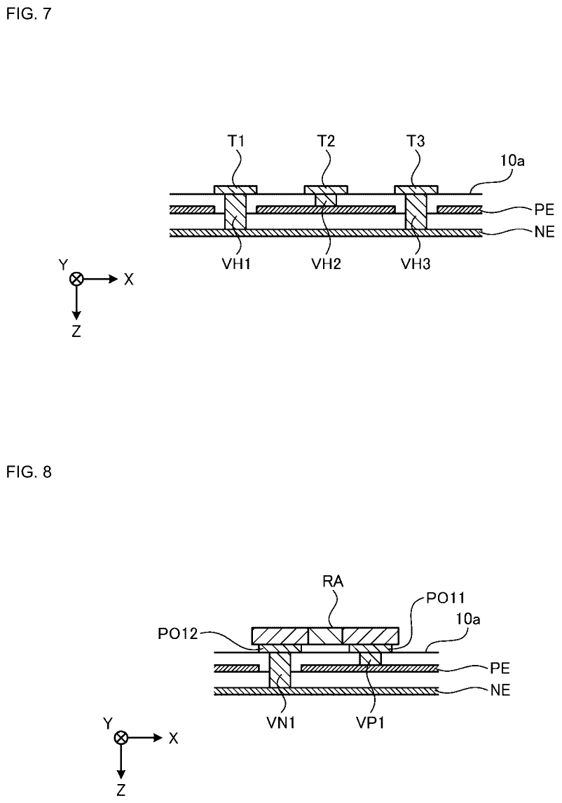

FIG. 6 is provided to describe a method for measuring S parameters of a multi-terminal capacitor. FIG. 6 illustrates a jig for measuring S parameters. FIG. 7 illustrates a section taken along line B1-B1 in FIG. 6. FIG. 8 illustrates a section taken along line B2-B2 in FIG. 6.

In FIG. 6, a substrate 10a is set on a jig 11. The substrate 10a is used to evaluate the multi-terminal capacitor 1. The multi-terminal capacitor 1 includes the substrate 10a.

The multi-terminal capacitor 1 includes the nine terminals T1 to T9. The terminals T2, T4, T6 and T8 are positive terminals electrically coupled to a positive electrode PE inside the substrate 10a. The terminals T1, T3, T5, 17 and T9 are negative terminals electrically coupled to a negative electrode NE inside the substrate 10a.

For example, as illustrated in FIG. 7, the terminal T1 is electrically coupled to the negative electrode NE inside the substrate 10a by the via-hole VH1. The terminal T1 is not coupled to the positive electrode PE inside the substrate 10a. The terminal T2 is electrically coupled to the positive electrode PE inside the substrate 10a by the via-hole VH2. The terminal T3 is electrically coupled to the negative electrode NE inside the substrate 10a by the via-hole VH3. The terminal T3 is not coupled to the positive electrode PE inside the substrate 10a. As described above, adjacent terminals in the X-axis direction differ from each other with respect to polarity, and adjacent terminals in the Y-axis direction differ from each other with respect to polarity. The positive and negative terminals are alternately arranged, or arranged in a staggered manner, in both the X-axis and Y-axis directions.

The substrate 10a includes ports PO1 and PO2. The port PO1 is provided on one side of the multi-terminal capacitor 1 in the Y-axis direction, and the port PO2 is provided on the other side of the multi-terminal capacitor 1. The port PO1 includes a positive pole PO11 and a negative pole PO12. The port PO2 includes a positive pole PO21 and a negative pole PO22.

To measure S parameters, a resistor RA is electrically coupled between the positive pole PO11 and the negative pole PO12 of the port PO1. Similarly, a resistor RB is electrically coupled between the positive pole PO21 and the negative pole PO22 of the port PO2. The resistors RA and RB are, for example, 50Ω chip resistors.

As illustrated in FIG. 8, the positive pole PO11 of the port PO1 is electrically coupled to the positive electrode PE inside the substrate 10a by a via-hole VP1. The negative pole PO12 of the port PO1 is electrically coupled to the negative electrode NE inside the substrate 10a by a via-hole VN1. The negative pole PO12 is not coupled to the positive electrode PE inside the substrate 10a. Similarly to the port PO1, the positive pole PO21 of the port PO2 is electrically coupled to the positive electrode PE inside the substrate 10a, and the negative pole PO22 of the port PO2 is electrically coupled to the negative electrode NE inside the substrate 10a.

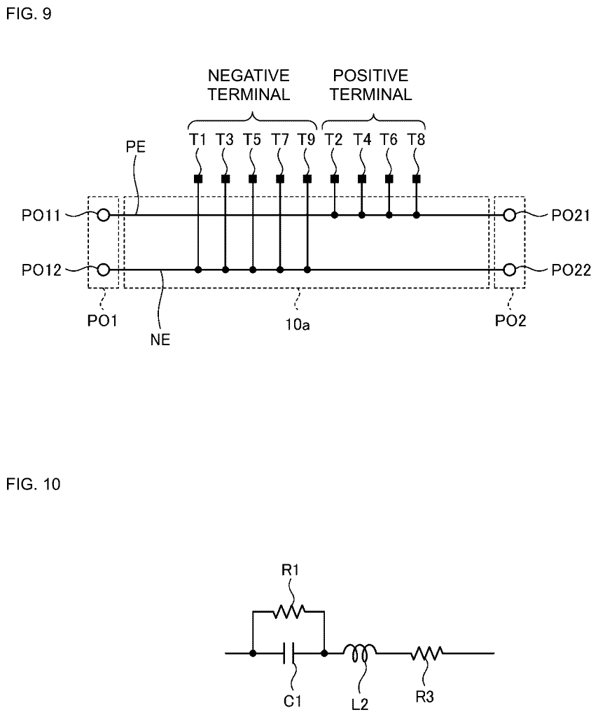

FIG. 9 illustrates an equivalent circuit of the substrate 10a including the multi-terminal capacitor 1. As illustrated in FIG. 9, the positive pole PO11 of the port PO1 is electrically coupled to the positive electrode PE. The positive pole PO21 of the port PO2 is electrically coupled to the positive electrode PE. The negative pole PO12 of the port PO1 is electrically coupled to the negative electrode NE. The negative pole PO22 of the port PO2 is electrically coupled to the negative electrode NE. The terminals T1, T3, T5, T7, and T9 are negative terminals and are electrically coupled to the negative electrode NE. The terminals T2, T4, T6, and T8 are positive terminals and are electrically coupled to the positive electrode PE.

The S parameters of the equivalent circuit illustrated in FIG. 9 are measured using a shunt-through method. At this time, for example, S parameters are measured using a network analyzer. S parameters, also referred to as a scattering matrix or scattering parameters, are parameters that represent the bandpass and reflection power characteristics of a circuit network.

Using the measured S parameters, a total impedance Zₜₒₜₐₗ of the circuit is calculated. The impedance Zₜₒₜₐₗ is derived according to the following expression (1).

$${Z}_{total} = ( {Z}_{0} / 2 ) \times \{ {S}_{21} / ( 1 - {S}_{21} ) \} \qquad ( 1 )$$

In Expression (1), Z₀ represents the characteristic impedance, and Se represents the power gain when the impedance of a power supply and a load is Z₀.

### Fitting Process

Next, the fitting process will be described. The fitting process is a process for deriving an equivalent circuit that corresponds to the measurement value of the total impedance Zₜₒₜₐₗ of the circuit. The fitting process is the process of matching simulation values to measurement values. Specifically, to match the impedance simulation value obtained from a simulation program with integrated circuit emphasis (SPICE) model to the measurement value, resistive elements, inductive elements, and capacitive elements are combined, so that an equivalent circuit is derived.

FIGS. 10 to 12 illustrate exemplary equivalent circuits for representing the total impedance Zₜₒₜₐₗ of the circuit. FIG. 10 illustrates a base configuration of the equivalent circuit. The equivalent circuit illustrated in FIG. 10 includes resistive elements R1 and R3, a capacitive element C1, and an inductive element L2. The capacitive element C1, the inductive element L2, and the resistive element R3 are coupled in series. The resistive element R1 is coupled in parallel with the capacitive element C1. The resistive element R1 represents an insulation resistance.

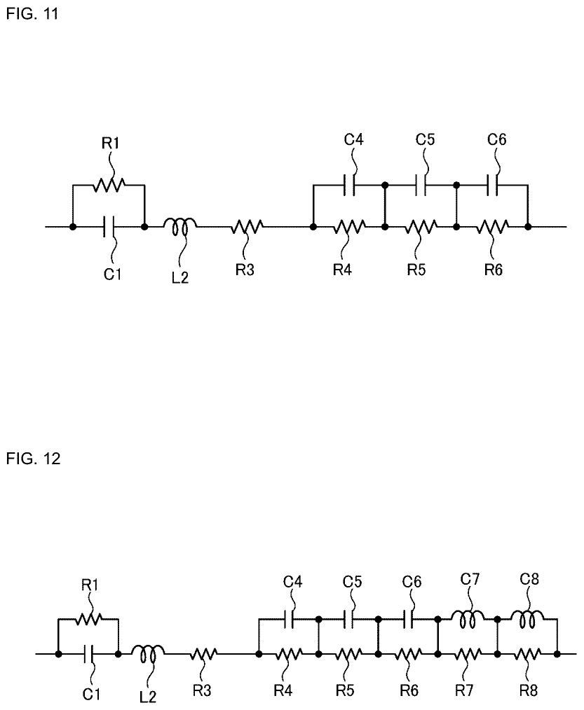

FIG. 11 illustrates an equivalent circuit for fitting across lower frequencies. The equivalent circuit illustrated in FIG. 11 includes resistive elements R1 and R3 to R6, capacitive elements C1 and C4 to C6, and an inductive element L2. The capacitive element C1, the inductive element L2, and the resistive elements R3, R4, R5, and R6 are coupled in series. The resistive element R1 is coupled in parallel with the capacitive element C1, the capacitive element C4 with the resistive element R4, the capacitive element C5 with the resistive element R5, and the capacitive element C6 with the resistive element R6. The resistive element R1 represents an insulation resistance.

FIG. 12 illustrates an equivalent circuit for fitting across an entire frequency range including lower frequencies. The equivalent circuit illustrated in FIG. 12 includes resistive elements R1 and R3 to R8, capacitive elements C1 and C4 to C6, and inductive elements L2, L7, and L8. The capacitive element C1, the inductive element L2, and the resistive elements R3, R4, R5, R6, R7, and R8 are coupled in series. The resistive element R1 is coupled in parallel with the capacitive element C1, the capacitive element C4 is coupled in parallel with the resistive element R4, the capacitive element C5 is coupled in parallel with the resistive element R5, the capacitive element C6 is coupled in parallel with the resistive element R6, the inductive element L7 is coupled in parallel with the resistive element R7, and the inductive element L8 is coupled in parallel with the resistive element R8. The resistive element R1 represents an insulation resistance.

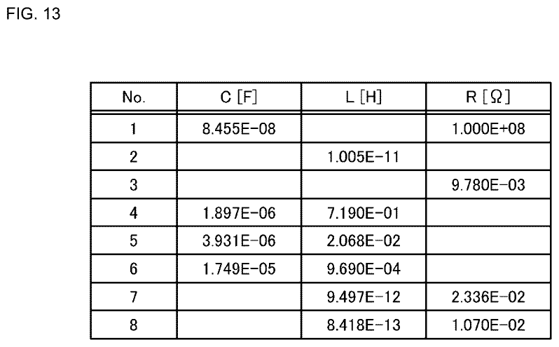

FIG. 13 is a table tabulating values of the elements included in the circuits illustrated in FIGS. 10 to 12. Specifically, the table in FIG. 13 indicates an example of capacitances [F] of the capacitive elements C, inductances [H] of the inductive elements L, and resistances [Q] of the resistive elements R. The reference numerals for the elements included in the circuits illustrated in FIGS. 10 to 12 are represented by combining numerals 1 to 8 in the “No.” field of the leftmost column of the table with the capacitive element C, the inductive element L, or the resistive element R. For example, the capacitance of the capacitive element C1 is about 8.455×10⁻⁸ [F], the inductance of the inductive element L2 is about 1.005×10⁻¹¹ [H], the resistance of the resistive element R1 is about 1.000×10⁸ [Ω], the resistance of the resistive element R3 is about 9.780×10⁻³ [Ω]. The values of the other elements are also indicated in the table in FIG. 13.

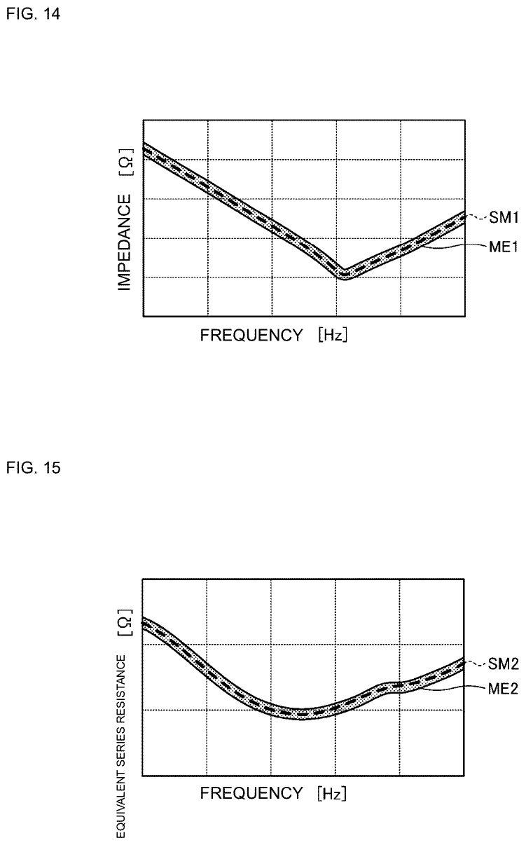

FIG. 14 illustrates an example of impedance changes with respect to frequency. In FIG. 14, the horizontal axis represents frequency [Hz] and the vertical axis represents impedance [Ω]. For example, as illustrated in FIGS. 10 to 12, by combining the capacitive elements C, the inductive elements L, and the resistive elements R, an impedance simulation value SM1 obtained from the SPICE model can be matched to a measurement value ME1. In other words, an equivalent circuit is created by coupling the capacitive elements C, the inductive elements L, and the resistive elements R so that the simulation value SM1 of the SPICE model matches the measurement value ME1.

FIG. 15 illustrates an example of equivalent series resistance (ESR) changes with respect to frequency. In FIG. 15, the horizontal axis represents frequency [Hz] and the vertical axis represents equivalent series resistance [Ω]. For example, as illustrated in FIGS. 10 to 12, by combining the capacitive elements C, the inductive elements L, and the resistive elements R, an equivalent series resistance simulation value SM2 obtained from the SPICE model can be matched to a measurement value ME2. In other words, an equivalent circuit is created by coupling the capacitive elements C, the inductive elements L, and the resistive elements R so that the simulation value SM2 of the SPICE model matches the measurement value ME2.

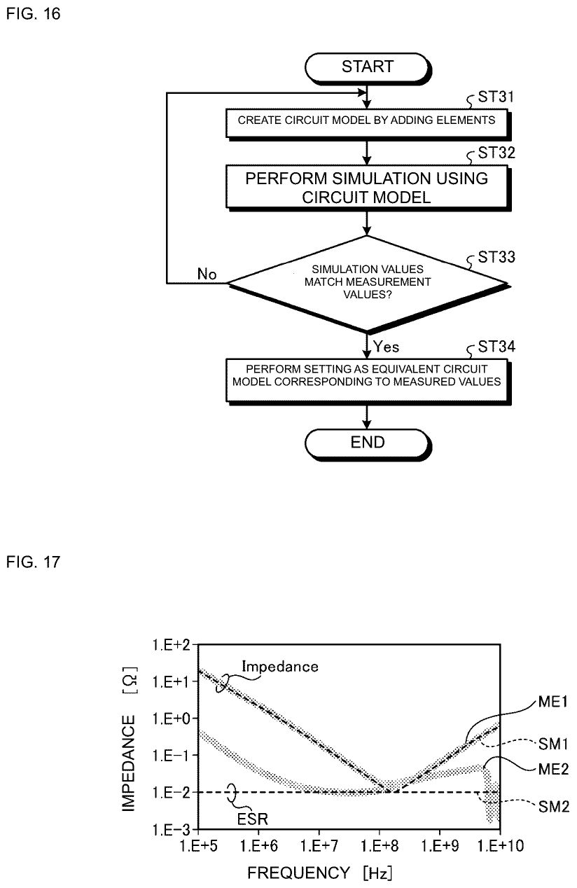

FIG. 16 is a flowchart illustrating an example of the fitting process. In FIG. 16, firstly, a circuit model is created by adding a resistive element, inductive element, or capacitive element (step ST31). A simulation is performed using the circuit model created by adding a resistive element, inductive element, or capacitive element (step ST32).

Next, a determination is made to assess whether the simulation values obtained from the circuit model created by adding a resistive element, inductive element, or capacitive element match measurement values (step ST33). As a result of the determination in step ST33, when the simulation values match the measurement value (Yes in step ST33), the circuit model corresponding to the simulation value is set as an equivalent circuit model corresponding to the measured total impedance value of the circuit (step ST34).

In contrast, as a result of the determination in step ST33, when the simulation values do not match the measurement values (No in step ST33), the process returns to step ST31, and a new circuit model is created by further adding a resistive element, inductive element, or capacitive element. A simulation using the new circuit model is performed (step ST32), and a determination is made to assess whether the simulation values from the circuit model match the measurement values (step ST33). The operations described above are repeated until the simulation values from a circuit model match the measurement values. By repeating the operations described above, the simulation values can be gradually adjusted to approximate the measurement values, and eventually, the simulation values can be matched to the measurement values. The simulation values matching the measurement values are used as the equivalent circuit model. By performing the fitting process using basic circuit elements such as resistive elements, inductive elements and capacitive elements, equivalent circuit models (for example, SPICE netlists) that are usable in general-purpose circuit simulators can be provided.

### Determination of Whether Match is Achieved

The determination of whether the simulation values match the measurement values in step ST33 in FIG. 16 may be made, for example, as follows. The measurement value is not constant and varies within ranges illustrated in FIGS. 14 and 15. When the simulation values continuously fall within the variation ranges of the measurement values, it can be determined that the simulation value matches the measurement value. Specifically, as illustrated in FIG. 14, the impedance measurement value ME1 varies within a specific variation range. When the simulation value SM1 continuously falls within the variation range of the measurement value ME1, it can be determined that the simulation value matches the measurement value. As illustrated in FIG. 15, the ESR measurement value ME2 varies within a specific variation range. When the simulation value SM2 continuously falls within the variation range of the measurement value ME2, it can be determined that the simulation value matches the measurement value.

It may be determined that the simulation values match the measurement values when the simulation values fall within specific variation ranges across a designated frequency range. For example, when the frequency band to be used is known in advance, a corresponding frequency range may be designated, and a determination may be made to assess whether the simulation values match the measurement values across the frequency range.

FIGS. 17 to 19 illustrate examples of the measurement values and the simulation values of impedance and ESR. In FIGS. 17 to 19, the horizontal axis represents frequency [Hz] and the vertical axis represents impedance [Ω]. By sequentially adding elements to create combinations as illustrated in the circuits in FIGS. 10 to 12, the process of matching the simulation value SM1 to the impedance measurement value ME1 and matching the simulation value SM2 to the ESR measurement value ME2, that is, the fitting process, is performed. At this time, by progressively adding elements to create various combinations, the waveform of the simulation value SM1 and the waveform of the simulation value SM2 can be matched to the measurement values ME1 and ME2 across lower to higher frequency ranges.

FIG. 17 corresponds to the equivalent circuit in FIG. 10. The equivalent circuit in FIG. 10 is an equivalent circuit using one resistive element for equivalent series resistance and one inductive element for equivalent series inductance. Since the equivalent series resistance is achieved with a small number of elements, the equivalent series resistance has a flat, frequency-independent characteristic as illustrated in FIG. 17.

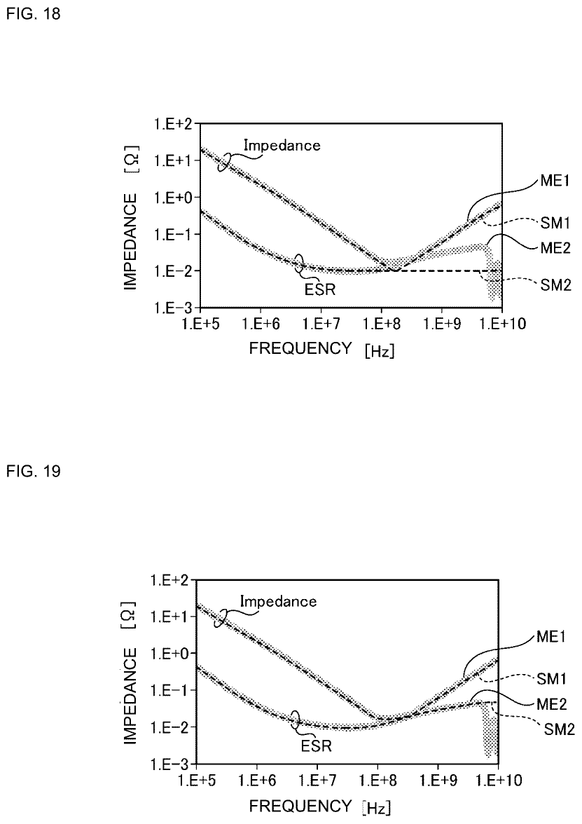

FIG. 18 corresponds to the equivalent circuit in FIG. 11. The equivalent circuit in FIG. 11 is an equivalent circuit created by additionally coupling three CR parallel circuits in series to the equivalent circuit in FIG. 10. As illustrated in FIG. 18, the frequency characteristic of the equivalent series resistance is reflected across lower frequencies.

FIG. 19 corresponds to the equivalent circuit in FIG. 12. The equivalent circuit in FIG. 12 is an equivalent circuit created by additionally coupling two LR parallel circuits in series to the equivalent circuit in FIG. 11. As illustrated in FIG. 19, the frequency characteristics of the impedance and the equivalent series resistance are reflected in the frequency region higher than the self-resonant frequency.

Overall, the precision of matching the simulation values to the measurement values is higher in the case of FIG. 18 with the equivalent circuit in FIG. 11 than in the case of FIG. 17 with the equivalent circuit in FIG. 10. The precision of matching the simulation values to the measurement values is higher in the case of FIG. 19 with the equivalent circuit in FIG. 12 than in the case of FIG. 18 with the equivalent circuit in FIG. 11. As described above, by adding resistive elements, inductive elements, and capacitive elements, the precision of matching the simulation values to the measurement values can be improved.

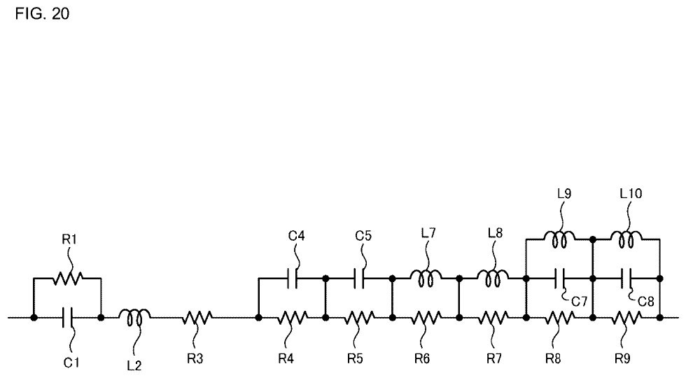

As a result of performing the fitting process of matching the simulation values to the measurement values as described above, for example, a unit cell illustrated in FIG. 20 can be obtained. FIG. 20 illustrates an exemplary unit cell. The unit cell illustrated in FIG. 20 includes resistive elements R1 and R3 to R9, capacitive elements C1, C4, C5, C7, and C8, and inductive elements L2 and L7 to L10. The capacitive element C1, the inductive element L2, and the resistive elements R3, R4, R5, R6, R7, R8, and R9 are coupled in series. The resistive element R1 is coupled in parallel with the capacitive element C1, the capacitive element C4 with the resistive element R4, the capacitive element C5 is coupled in parallel with the resistive element R5, the inductive element L7 is coupled in parallel with the resistive element R6, the inductive element L8 is coupled in parallel with the resistive element R7, the capacitive element C7 and the inductive element L9 is coupled in parallel with the resistive element R8, and the capacitive element C8 and the inductive element L10 are coupled in parallel with the resistive element R9. The resistive element R1 represents an insulation resistance.

### Array of Unit Cells

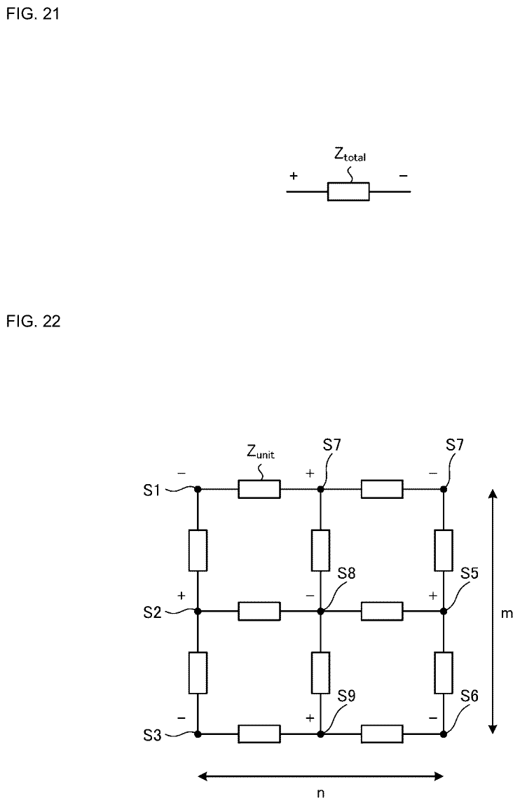

FIG. 21 illustrates an image of the total impedance Zₜₒₜₐₗ. FIG. 22 illustrates an exemplary array of unit cells that corresponds to the total impedance Zₜₒₜₐₗ.

In FIG. 21, one end of the total impedance Zₜₒₜₐₗ corresponds to the positive pole (+), and the other end corresponds to the negative pole (−). The total impedance Zₜₒₜₐₗ is converted into an array including m rows and n columns (m and n are natural numbers). In this example, when the array includes m rows and n columns, the impedance Zᵤₙᵢₜ of a unit cell is determined by multiplying the total impedance Zₜₒₜₐₗ by a unit cell count K, which is the number of unit cells, given by K=2 mn−m−n. Specifically, the impedance Zᵤₙᵢₜ of a unit cell is given by the following expression (2).

$${Z}_{unit} = K \cdot {Z}_{total} \qquad ( 2 )$$

Using the above expression, the impedance of a unit cell is derived from the total impedance, while the specific periodic structure of the array is taken into account. For example, when the array is 3×3 as illustrated in FIG. 22, m=3 and n=3; accordingly, the unit cell count K is K=2·3·3−3−3=12. Thus, as illustrated in FIG. 22, twelve unit cells are arranged in a matrix, in other words, coupled in series and in parallel. In this example, different weighting coefficients are assigned to individual impedance locations between terminals, that is, locations at which unit cells are arranged in a matrix. Each impedance is multiplied by a corresponding weighting coefficient.

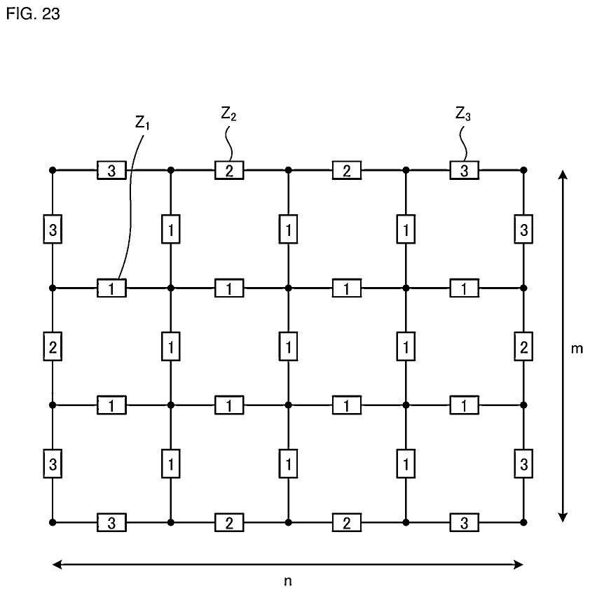

FIG. 23 illustrates weighting coefficients that correspond to specific locations. FIG. 23 illustrates an arrangement of unit cells in a grid pattern with m rows and n columns. In FIG. 23, a symbol denoted by a rectangle enclosing the numeral “1” represents an impedance Z₁. The impedance Z₁ is an element positioned inside the grid. In other words, the impedance Z₁ is positioned at a location within the grid, excluding the peripheries. The impedance Z₁ corresponds to a value obtained by multiplying the total impedance Zₜₒₜₐₗ by a weighting coefficient K₁.

In FIG. 23, a symbol denoted by a rectangle enclosing the numeral “2” represents an impedance Z₂. The impedance Z₂ is an element positioned at the side portions of the peripheries of the grid, excluding the corner portions. The impedance Z₂ corresponds to a value obtained by multiplying the total impedance Zₜₒₜₐₗ by a weighting coefficient K₂.

In FIG. 23, a symbol denoted by a rectangle enclosing the numeral “3” represents an impedance Z₃. An impedance Z₃ is an element positioned on the corner portions of the peripheries of the grid. The impedance Z₃ corresponds to a value obtained by multiplying the total impedance Zₜₒₜₐₗ by a weighting coefficient K₃.

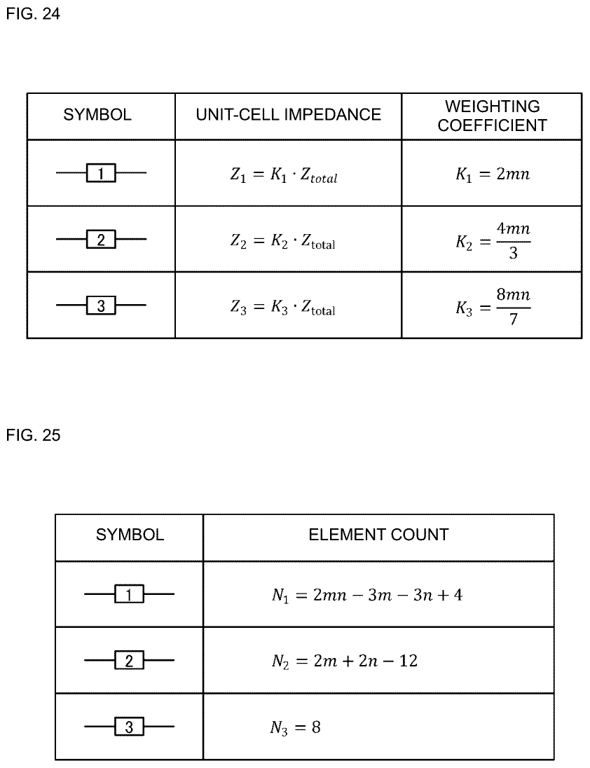

Referring to FIG. 24, an example of the weighting coefficients K₁, K₂, and K₃ will be described. FIG. 24 is a table indicating weighting coefficients for the individual symbols. As illustrated in FIG. 24, the weighting coefficients K₁, K₂, and K₃ are provided by the following expressions (3) to (5).

$${K}_{1} = 2 mn \qquad ( 3 )$$

$${K}_{2} = 4 mn / 3 \qquad ( 4 )$$

$${K}_{3} = 8 mn / 7 \qquad ( 5 )$$

In Expressions (3) to (5), for example, m≥3, and n≥3. Given the designated weighting coefficients, the total impedance Zₜₒₜₐₗ is calculated by summing the reciprocals of the impedances Z₁, Z₂, and Z₃ of the individual elements. This means that the total impedance Zₜₒₜₐₗ is calculated by summing the admittances.

FIG. 25 is a table indicating the count of elements corresponding to each symbol. As illustrated in FIG. 25, provided that N₁ represents the count of elements corresponding to the symbol denoted a rectangle enclosing the numeral “1”, N₂ represents the count of elements corresponding to the symbol denoted by a rectangle enclosing the numeral “2”, and N₃ represents the count of elements corresponding to the symbol consisting of a rectangle enclosing the numeral “3”, the counts N₁, N₂, and N₃ are provided by the following expressions (6) to (8).

$${N}_{1} = 2 mn - 3 m - 3 n + 4 \qquad ( 6 )$$

$${N}_{2} = 2 m + 2 n - 12 \qquad ( 7 )$$

$${N}_{3} = 8 \qquad ( 8 )$$

The identity satisfied by the counts N₁, N₂, and N₃ is as follows.

$$( 1 / 2 ) \cdot {N}_{1} + ( 3 / 4 ) \cdot {N}_{2} + 7 / 8 \cdot {N}_{3} = mn \qquad ( 9 )$$

Using the weighting coefficients, the relationship among the counts N₁, N₂, and N₃ is represented by Expression (10).

$$( {N}_{1} / {K}_{1} ) + ( {N}_{2} / {K}_{2} ) + ( {N}_{3} / {K}_{3} ) = 1 \qquad ( 10 )$$

The total impedance Zₜₒₜₐₗ satisfies the identity provided in the following expression (11).

$$( {N}_{1} / {Z}_{1} ) + ( {N}_{2} / {Z}_{2} ) + ( {N}_{3} / {Z}_{3} ) = 1 / {Z}_{total} \qquad ( 11 )$$

To divide the total impedance Zₜₒₜₐₗ into twelve unit cells coupled in a matrix, the resistance and inductance are multiplied by 6 (K=6), and the capacitance is multiplied by ⅙ (K=6). Specifically, a resistance Rᵤₙᵢₜ of a unit cell is provided by the following expression (12), an inductance Lᵤₙᵢₜ of the unit cell is provided by the following expression (13), and a capacitance Cᵤₙᵢₜ of the unit cell is provided by the following expression (14).

$${R}_{unit} = K \cdot {R}_{total} \qquad ( 12 )$$

$${L}_{unit} = K \cdot {L}_{total} \qquad ( 13 )$$

$${C}_{unit} = {C}_{total} / K \qquad ( 14 )$$

In Expression (12), Rₜₒₜₐₗ represents the resistance of the resistive element before the division into unit cells. Un Expression (13), Lₜₒₜₐₗ represents the inductance of the inductive element before the division into unit cells. In Expression (14), Cₜₒₜₐₗ represents the capacitance of the capacitive element before the division into unit cells.

In other words, for the division into K unit cells coupled in a matrix, the resistance and inductance are multiplied by K, and the capacitance is multiplied by 1/K. In this manner, the values of each element are multiplied by K or 1/K and assigned to each unit cell.

As a result of determining the values of each element as represented by the above expressions (12) to (14), the combined impedance of all of the elements becomes equal or substantially equal to the original impedance Zₜₒₜₐₗ.

Expressions (12) to (14) are created without applying any weights. When the weighting coefficients K₁, K₂, and K₃ are applied, K₁=18, K₂=12, and K₃=72/7, according to Expressions (3) to (5). To calculate resistances Rᵤₙᵢₜ₁, Rᵤₙᵢₜ₂, Rᵤₙᵢₜ₃, inductances Lᵤₙᵢₜ₁, Lᵤₙᵢₜ₂, Lᵤₙᵢₜ₃, and capacitances Cᵤₙᵢₜ₁, Cᵤₙᵢₜ₂, and Cᵤₙᵢₜ₃ of unit cells using the weighting coefficients, the following expressions are used instead of Expressions (12), (13), and (14).

For the weighting coefficient K₁, Expressions (12.1) to (14.1) are used.

$${R}_{unit 1} = {K}_{1} \cdot {R}_{total} \qquad ( 12.1 )$$

$${L}_{unit 1} = {K}_{1} \cdot {L}_{total} \qquad ( 13.1 )$$

$${C}_{unit 1} = {C}_{total} / {K}_{1} \qquad ( 14.1 )$$

For the weighting coefficient K₂, Expressions (12.2) to (14.2) are used.

$${R}_{unit 2} = {K}_{2} \cdot {R}_{total} \qquad ( 12.2 )$$

$${L}_{unit 2} = {K}_{2} \cdot {L}_{total} \qquad ( 13.2 )$$

$${C}_{unit 2} = {C}_{total} / {K}_{2} \qquad ( 14.2 )$$

For the weighting coefficient K₃, Expressions (12.3) to (14.3) are used.

$${R}_{unit 3} = {K}_{3} \cdot {R}_{total} \qquad ( 12.3 )$$

$${L}_{unit 3} = {K}_{3} \cdot {L}_{total} \qquad ( 13.3 )$$

$${C}_{unit 3} = {C}_{total} / {K}_{3} \qquad ( 14.3 )$$

In other words, for the division into K unit cells coupled in a matrix, the resistance and inductance are multiplied by K₁, K₂, and K₃, and the capacitance is multiplied by 1/K₁, 1/K₂, and 1/K₃. In this manner, the values of each element are multiplied by K₁, K₂, and K₃ or 1/K₁, 1/K₂, and 1/K₃, and assigned to each unit cell.

By setting weighting coefficients as described above, proper weighting can be achieved for any arrays with m rows and n columns. Specifically, proper weighting can be achieved for the impedance Z₁ of the elements positioned inside the grid, the impedance Z₂ of the elements positioned at the peripheries of the grid, excluding the corner portions, and the impedance Z₃ of the elements at the corner portions of the peripheries of the grid, irrespective of whether the array changes.

The foregoing discussion assumes that each unit cell arranged in m rows and n columns is of the same or substantially the same size. In other words, it is assumed that regions of the same or substantially the same area size in plan view are arranged in m rows and n columns, and the electrode within the substrate is equally divided. In practice, the regions often do not have an the same or substantially the same area size in plan view. Thus, it is preferable to set weighting coefficients with consideration for such cases. For example, a portion corresponding to an electrode portion positioned at the peripheries may extend outward. Since this extended portion has a relatively large parasitic capacitance, taking this extended portion into account is preferable. When the electrode within the substrate is not equally divided as described above, adjusting weighting coefficients enables more accurate simulation. Specifically, when some unit cells are positioned at the peripheries of the matrix, and the electrode portion corresponding to the unit cells is extended, weighting coefficients are set with consideration for the extended portion.

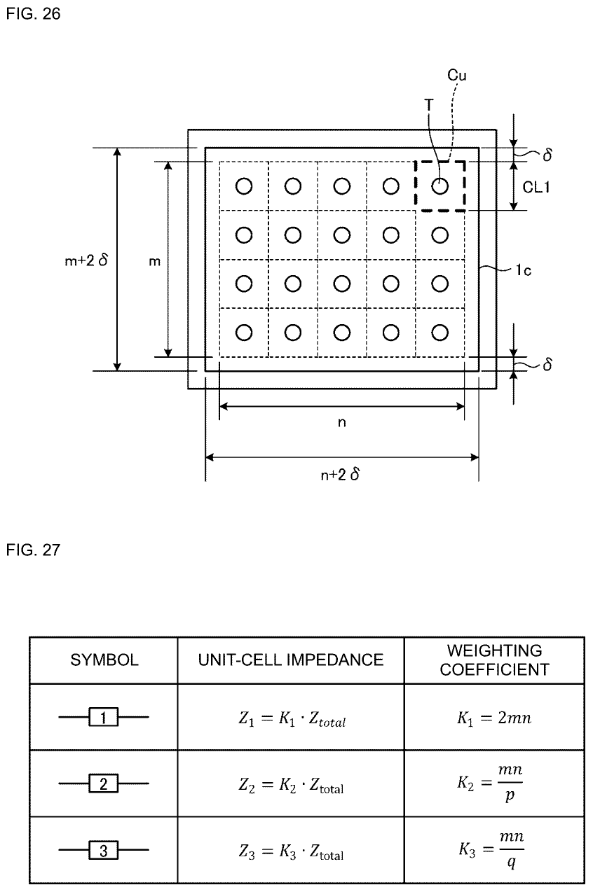

In the present disclosure, an extension coefficient δ is provided. The extension coefficient δ is applied to the extended electrode portion corresponding to the unit cells positioned at the peripheries. FIG. 26 illustrates the definition of the extension coefficient δ. The extension coefficient δ represents the ratio of a portion at which the inner electrode extends outward beyond the array of unit cells.

As illustrated in FIG. 26, unit cells Cu are arranged in m rows and n columns at a substrate 1c. Terminals T are provided in the individual unit cells Cu. A region 1ce corresponding to an inner electrode of the substrate 1c extends outward beyond the region corresponding the unit cells Cu arranged in m rows and n columns. Given that a width CL1 of the vertical and horizontal dimensions of the unit cell is “1,” the region 1ce corresponding to the inner electrode measures, for example, “m+2δ” for “m” and “n+2δ” for “n”. The extension width in the vertical and horizontal directions is about 2δ. In this example, since the width CL1 of the unit cell is “1”, the extension coefficient is provided by δ/1=δ. Therefore, the width of the portion extending outward beyond the array of unit cells represents the extension coefficient δ.

### Ratio of Width to Length of Unit Cell

In this example, when the extended portion is taken into account, the effective unit cell count is, for example, (m+2δ) (n+2δ), instead of mn. In this case, the count of each element (N₁, N₂, N₃) satisfies the following identity (15).

$$( 1 / 2 ) {N}_{1} + p {N}_{2} + q {N}_{3} = ( m + 2 δ ) ( n + 2 δ ) \qquad ( 15 )$$

Among the weighting coefficients K₁ to K₃, the weighting coefficients K₂ and K₃ are adjusted to match the outer dimensions of the inner electrode. The weighting coefficients K₁, K₂, and K₃ will be exemplified below. FIG. 27 is a table indicating exemplary weighting coefficients for the individual symbols. As indicated in FIG. 27, the weighting coefficients K₁, K₂, and K₃ are provided by the following expressions (3), (4a), and (5a).

$${K}_{1} = 2 mn \qquad ( 3 )$$

$${K}_{2} = mn / p \qquad ( 4 a )$$

$${K}_{3} = mn / q \qquad ( 5 a )$$

In Expressions (3), (4a), and (5a), for example, m≥3, and n≥3.

In Expression (4a), a value p is provided by the following expression (16).

$$p = ( 3 / 4 ) + δ \qquad ( 16 )$$

In Expression (5a), a value q is provided by the following expression (17).

$$q = ( 7 / 8 ) + ( 3 δ / 2 ) + ( δ 2 / 2 ) \qquad ( 17 )$$

Given that the extension coefficient δ=0 in Expressions (16) and (17), Expression (4a) is the same or substantially the same as Expression (4), and Expression (5a) is the same or substantially the same as Expression (5).

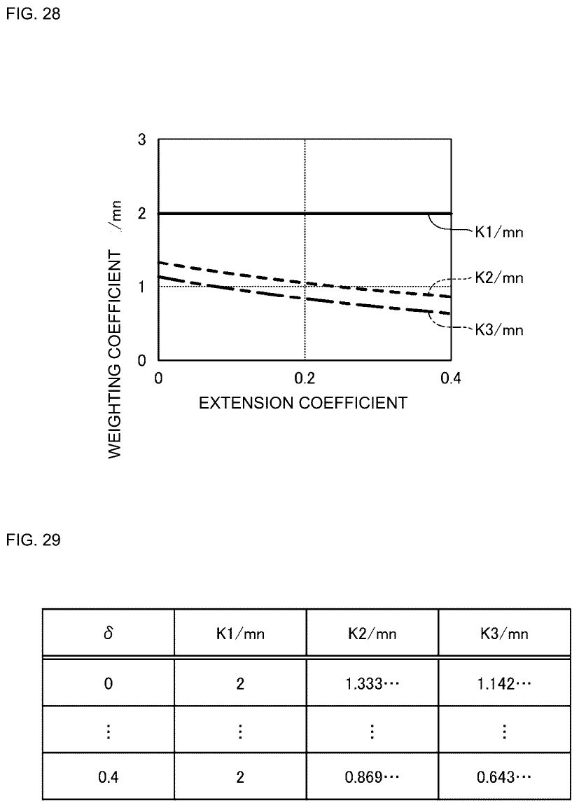

FIG. 28 illustrates the relationship between the extension coefficient and the weighting coefficients. In FIG. 28, the horizontal axis represents the extension coefficient δ, and the vertical axis represents the ratio of the weighting coefficient to the unit cell count mn. In FIG. 28, the solid line illustrates the change in the ratio of the weighting coefficient K₁ to the unit cell count mn. The dashed line illustrates the change in the ratio of the weighting coefficient K to the unit cell count mn. The dot-dash line illustrates the change in the ratio of the weighting coefficient K₃ to the unit cell count mn.

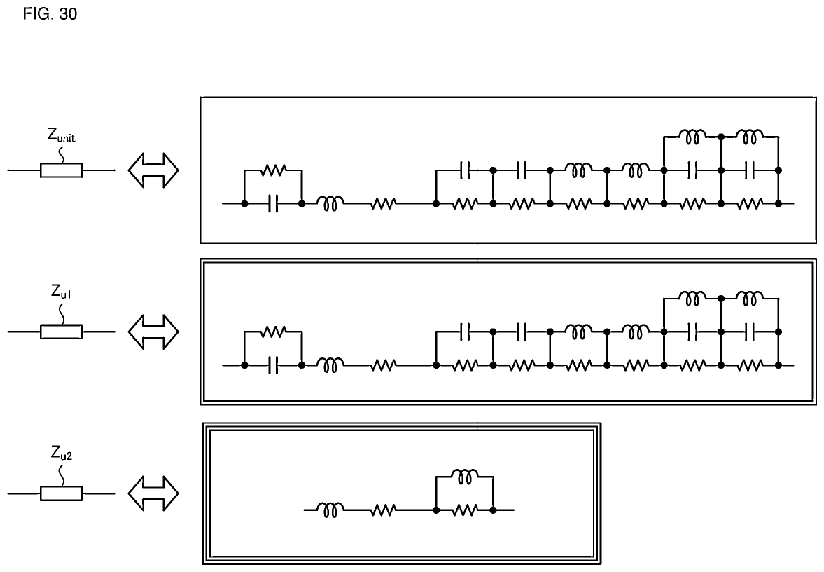

FIG. 29 is a table indicating the relationship between the extension coefficient and the weighting coefficient. FIG. 29 indicates an example of ratios K₁/mn, K₂/mn, and K₃/mn when the extension coefficient δ=0 and an example of the ratios K₁/mn, K₂/mn, and K₃/mn when the extension coefficient δ=0.4, where the ratios K₁/mn, K₂/mn, and K₃/mn represents the ratios of the respective weighting coefficients K₁, K₂, and K₃ to the count of portions arranged in m rows and n columns. It should be noted that, for example, K₂/mn=1/p, and K₃/mn=1/q.

In this example, when the extension coefficient δ=0, the ratio K₁/mn is about 2, and the ratio K₂/mn is approximately 1.333, and the ratio K₃/mn is approximately 1.142. In this example, when the extension coefficient δ=0.4, the ratio K₁/mn is about 2, and the ratio K₂/mn is approximately 0.869, and the ratio K₃/mn is approximately 0.643. Considering that the outer dimensions of the inner electrode vary according to design freedom, in other words, the extension coefficient varies, the weighting coefficients can be practically set within the range indicated in FIG. 29.

FIG. 30 illustrates elements that implement the impedances of unit cells. The impedance Zᵤₙᵢₜ of a unit cell illustrated in FIG. 30 is determined without taking into account the parasitic component of wires at the mounting board. In this example, in FIG. 30, it is assumed that the impedance Zᵤₙᵢₜ of a unit cell is divided into an impedance Zᵤ₁ of a first element and an impedance Zᵤ₂ of a second element. Specifically, the impedance Zᵤₙᵢₜ, which represents an element of an equivalent circuit model, can be divided into the impedance Zᵤ₁, which represents the first element that is a main component, and the impedance Zᵤ₂, which is a second element that is a parasitic component. The impedance Zᵤ₂, which is the second element, corresponds to the parasitic component of the wires at the mounting board. By considering the second element, simulation results that account for the parasitic component exerted by the actual substrate wires can be obtained. The impedance Zᵤ₂ as the second element is included in this example by an inductive element and two resistive elements that are coupled in series, and another inductive element that is coupled in parallel with one of the resistive elements.

In the drawings referred to in the following description, the impedance Zᵤₙᵢₜ of the unit cell is represented by a thick solid line, the impedance Zᵤ₁ of the first element is represented by a double line, and the impedance Zᵤ₂ of the second element is represented by a triple line.

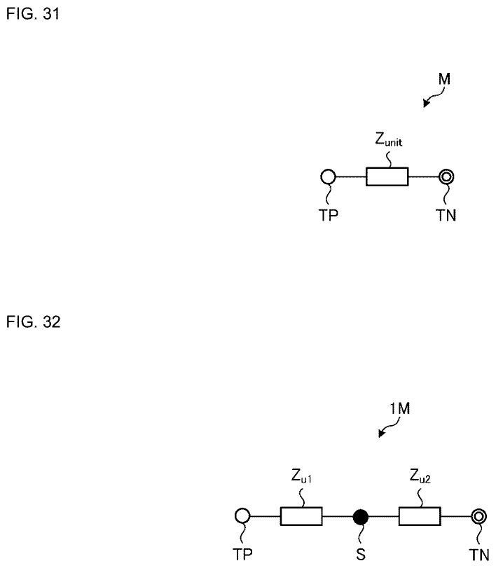

FIGS. 31 to 36 illustrates a process of creating a three-dimensional model from a unit cell. FIG. 31 illustrates an exemplary model of a unit cell. In a unit cell model M illustrated in FIG. 31, one end of the impedance Zᵤₙᵢₜ corresponds to a positive pole TP, and the other end corresponds to a negative pole TN. In FIG. 31, the negative pole TN is represented by a double circle. The same holds for the drawings referenced in the following.

FIG. 32 illustrates a one-dimensional model 1M that corresponds to the impedance Zᵤₙᵢₜ in FIG. 31. In FIG. 32, the impedances Zᵤ₁ and Zᵤ₂ are coupled in series. Across a node S, one side corresponds to the impedance Zᵤ₁ as the first element, and the other side corresponds to the impedance Zᵤ₂ as the second element. One end of the impedance Zᵤ₁ corresponds to the node S, and the other end corresponds to the positive pole TP. One end of the impedance Zᵤ₂ corresponds to the node S, and the other end corresponds to the negative pole TN. In this example, the impedance Zᵤ₁ corresponds to a capacitive circuit element, and the impedance Zᵤ₂ corresponds to an inductive circuit element.

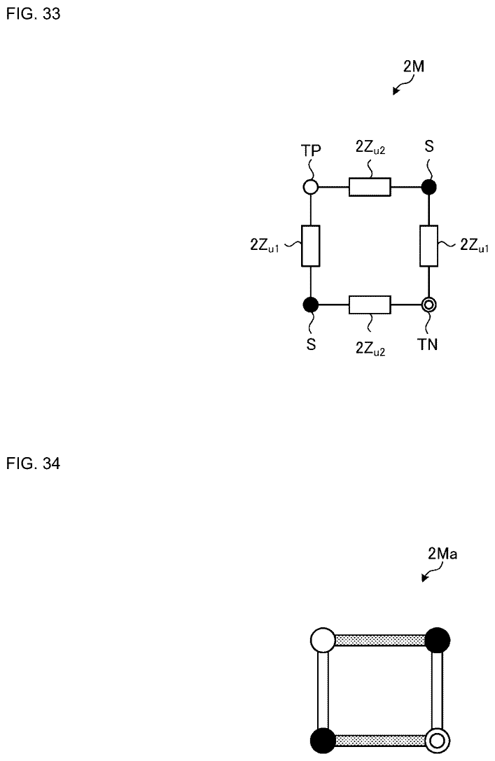

FIG. 33 illustrates a two-dimensional model 2M that corresponds to the one-dimensional model 1M in FIG. 32. It is considered that the impedance Zᵤ₁ in FIG. 32 is divided into two, and the impedance Zᵤ₂ is divided into two. In that case, as illustrated in FIG. 33, 2Zᵤ₁ is coupled between one node S and the positive pole TP, and “2Zᵤ₂” is coupled between the node S and the negative pole TN. Additionally, “2Zᵤ₂” is coupled between the other node S and the positive pole TP, and “2Zᵤ₁” is coupled between the node S and the negative pole TN. As described above, the two-dimensional model is provided by coupling values equal or substantially equal to twice the previous impedances to the respective sides of each node S.

In the two-dimensional model 2M illustrated in FIG. 33, series-connected combinations of “2Zᵤ₁” and “2Zᵤ₂” are coupled in parallel. As a result, the combined impedance between the positive pole TP and the negative pole TN is equal or substantially equal to the impedance in the one-dimensional model 1M in FIG. 32.

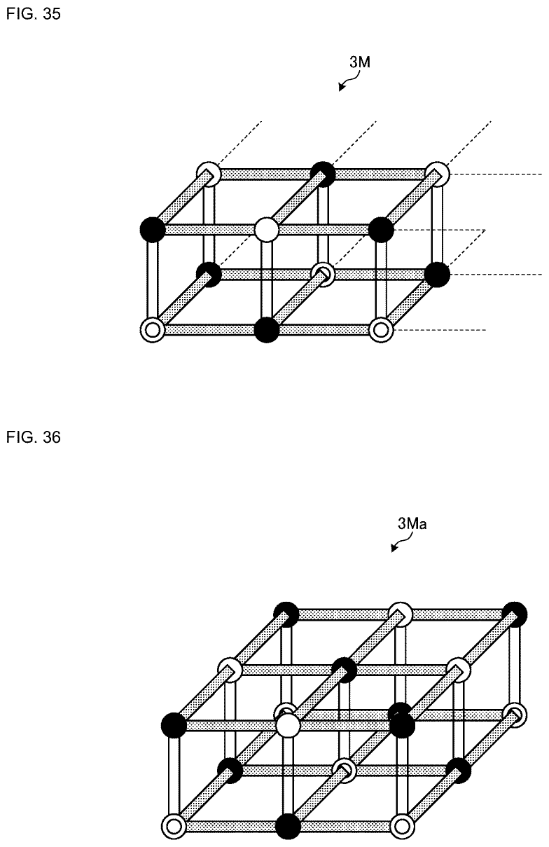

FIG. 34 illustrates a two-dimensional model 2Ma that is a simplified representation of the two-dimensional model 2M illustrated in FIG. 33. In the two-dimensional model 2Ma in FIG. 34, “2Zᵤ₁” in FIG. 33 is illustrated by double lines and “2Zᵤ₂” in FIG. 33 is illustrated by thick solid lines (hatched solid lines).

FIG. 35 illustrates a three-dimensional model 3M provided by repeatedly combining the simply represented two-dimensional model 2Ma illustrated in FIG. 34. The three-dimensional model 3M illustrated in FIG. 35 is provided by repeatedly combining the two-dimensional model illustrated in FIG. 34 into a three-dimensional grid. By repeatedly combining the two-dimensional model illustrated in FIG. 34 in any appropriate manner, multi-terminal three-dimensional models can be provided.

FIG. 36 illustrates an exemplary three-dimensional model provided by repeatedly combining the simply represented two-dimensional model 2Ma illustrated in FIG. 34. A three-dimensional model 3Ma illustrated in FIG. 36 is a three-dimensional model with nine terminals arranged in three rows and three columns. By repeatedly combining the two-dimensional model 2Ma illustrated in FIG. 34, three-dimensional models with increased numbers of terminals can be provided.

In FIG. 36, assuming that all of the positive poles are at the same potential, and all of the negative poles are at the same potential, the three-dimensional model can be folded and transformed back into a two-dimensional model by merging two nodes S into a single node. Overall, two-dimensional models can be transformed into three-dimensional models, and three-dimensional models can be transformed back into two-dimensional models.

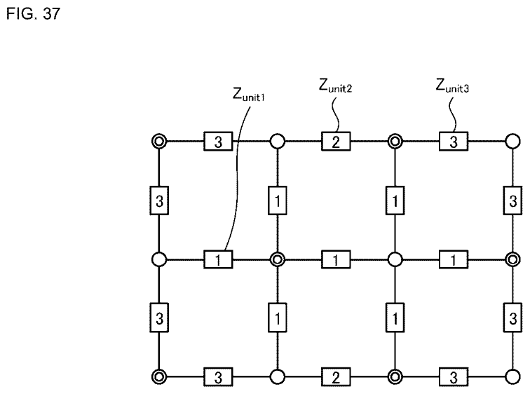

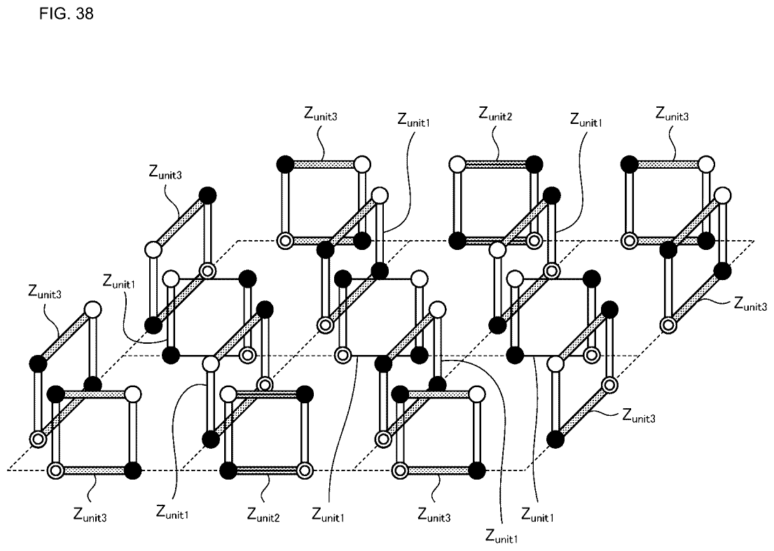

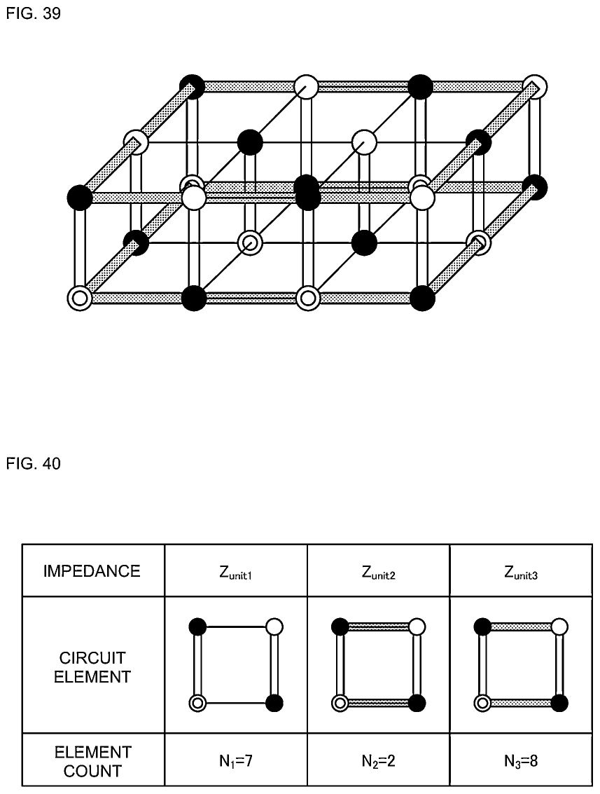

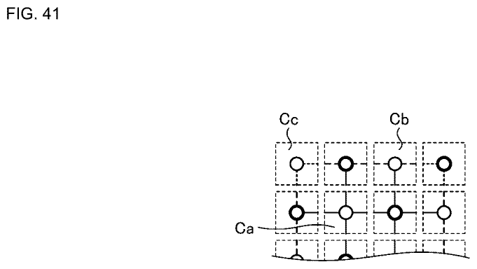

FIGS. 37 to 40 illustrate an exemplary three-dimensional model including twelve terminals arranged in three rows and four columns. The unit cell impedances Z₁, Z₂, and Z₃ of the two-dimensional models need to be repeatedly combined to match the symbols denoted by rectangles enclosing the numerals “1”, “2”, and “3” illustrated in FIG. 37. In this case, as illustrated in FIG. 38, seven impedances Z₁, two impedances Z₂, and eight impedances Z₃ are provided. As a result of repeatedly combining the impedances Z₁, Z₂, and Z₃ illustrated in FIG. 38, a three-dimensional model illustrated in FIG. 39 is obtained. In the three-dimensional model illustrated in FIG. 39, the count N₁ of the impedance Z₁ is “7,” the count Ne of the impedance Z₂ is “2,” and the count N₃ of the impedance Z₃ is “8” as indicated in FIG. 40.

The total impedance Zₜₒₜₐₗ satisfies the identity given in Expression (11) presented above. This means that the reciprocal of the total impedance is equal or substantially equal to the sum of the reciprocals of the impedances Z₁, Z₂, and Z₃.

Assuming that all of the positive poles are at the same potential, and all of the negative poles are at the same potential, the three-dimensional model illustrated in FIG. 39 can also be transformed into a two-dimensional model by merging two nodes S into a single node.

### Circuit Diagram Symbol

Next, a procedure for conversion into circuit diagram symbols will be described. FIGS. 41 to 43 illustrate a procedure for converting a three-dimensional model into circuit diagram symbols. Referring to FIG. 41, the cells defining the three-dimensional model can be classified into a cell Ca positioned inside, a cell Cb positioned at the side portions excluding the corner portions, and a cell Cc positioned at the corner portions.

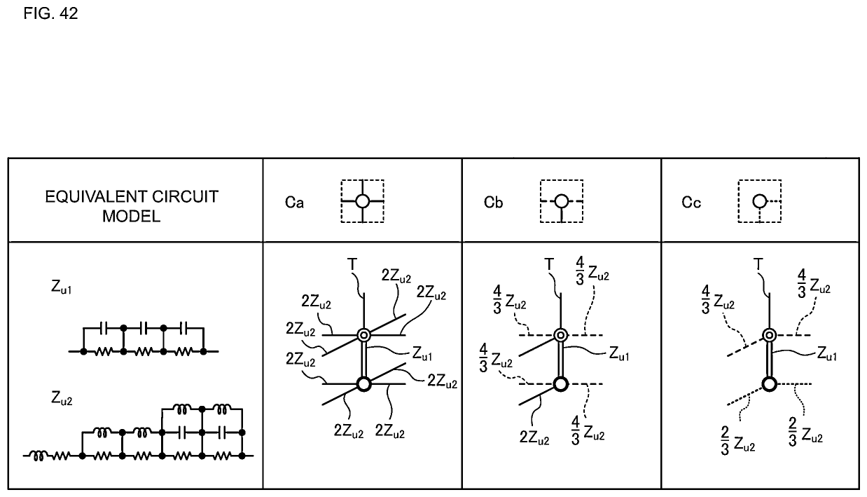

Referring to FIG. 42, for the impedances Zᵤ₁ and Zᵤ₂ of the equivalent circuit models in the table, the cell Ca, which is positioned inside, includes eight terminals for coupling with adjacent cells. The cell Ca includes eight impedances “2Zᵤ₂” and one impedance “Zᵤ₁”. The cell Ca also includes a terminal T for coupling with an external terminal.

The cell Cb, which is positioned at the side portions excluding the corner portions, includes six terminals for coupling with adjacent cells. The Cell Cb includes four impedances “(4/3) Zᵤ₂”, two impedances “2Zᵤ₂”, and one impedance “Zᵤ₁”. The cell Cb also includes a terminal T for coupling with an external terminal.

The cell Cc, which is positioned at the corner portions, includes four terminals for coupling with adjacent cells. The cell Cc includes two impedances “(3/4) Zᵤ₂”, two impedances “(2/3) Zᵤ₁”, and one impedance “Zᵤ₁”. The cell Cc also includes a terminal T for coupling with an external terminal.

### Example of Symbol

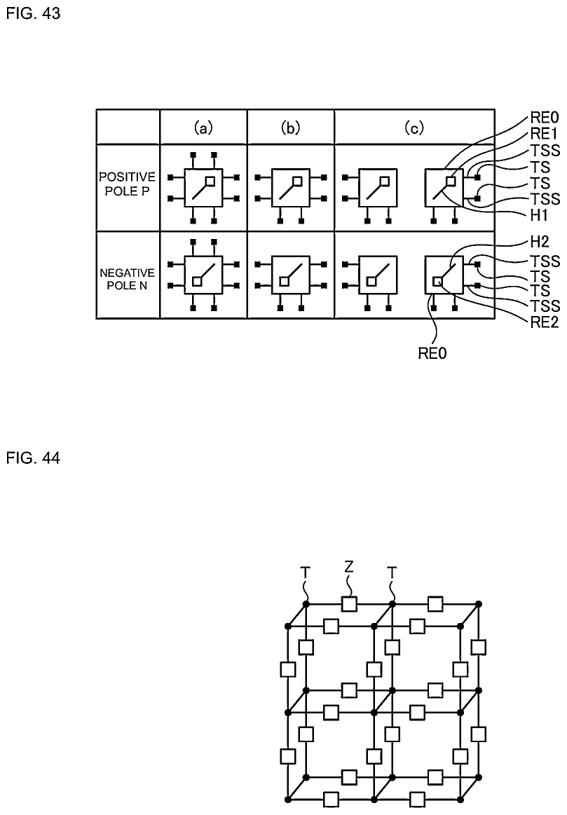

The equivalent circuit models of multi-terminal capacitors can be represented by symbols. FIG. 43 is a table illustrating an example of symbols for representing equivalent circuit models of multi-terminal capacitors.

FIG. 43 illustrates symbols of the individual cells corresponding to two kinds of poles, specifically positive pole P and negative pole N. The items of (a) in FIG. 43 are symbols representing cells inside the array, that is, cells positioned at neither the corner portions nor the side portions. The items of (b) in FIG. 43 are symbols representing cells positioned at the side portions excluding the corner portions. The items of (c) in FIG. 43 are symbols representing cells positioned at the corner portions.

In FIG. 43, the symbols for the positive pole P are denoted by a white rectangle RE0, a rectangle RE1 positioned at the upper right of the rectangle RE0, a line segment H1 extending from the rectangle RE1 toward the lower left of the rectangle RE0, black rectangles TS positioned outside the rectangle RE0, and line segments TSS connecting the rectangle RE0 and the rectangles TS. The black rectangles TS represent terminals coupled to adjacent cells. The number of rectangles TS is eight in the items of (a) in FIG. 43. This means that eight terminals are provided. The number of rectangles TS is six in the items of (b) in FIG. 43. This means that six terminals are provided. The number of rectangles TS is four in the items of (c) in FIG. 43. This means that four terminals are provided.

In FIG. 43, the symbols for the negative pole N are denoted by a white rectangle RE0, a rectangle RE2 positioned at the lower left of the rectangle RE0, a line segment H2 extending from the rectangle RE2 toward the upper right of the rectangle RE0, black rectangles TS positioned outside the rectangle RE0, and line segments TSS connecting the rectangle RE0 and the rectangles TS. The black rectangles TS represent terminals coupled to adjacent cells. The number of rectangles TS is eight in the items of (a) in FIG. 43. This means that eight terminals are provided. The number of rectangles TS is six in the items of (b) in FIG. 43. This means that six terminals are provided. The number of rectangles TS is four in the items of (c) in FIG. 43. This means that four terminals are provided.

FIG. 43 illustrates an example in which the symbols represent a grid divisions. However, other kinds of symbols may be used.

FIG. 44 illustrates an exemplary three-dimensional model including a terminal arrangement in three rows and three columns. In the three-dimensional model illustrated in FIG. 44, an impedance Z between terminals T is represented by a rectangle.

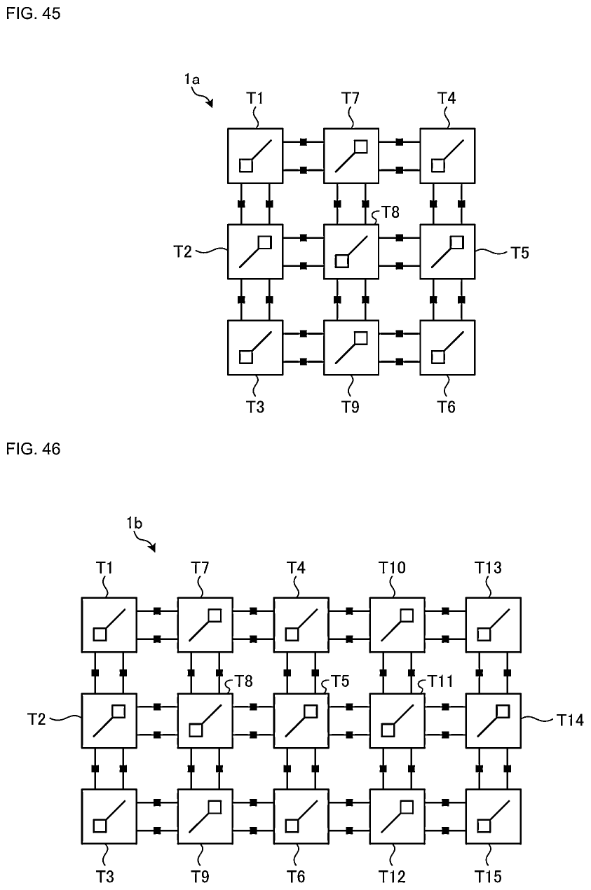

FIG. 45 illustrates an exemplary component model visualized using the symbols illustrated in FIG. 43. FIG. 45 illustrates a component model visualized using the symbols illustrated in FIG. 43, based on the three-dimensional model in FIG. 44. The three-dimensional model in FIG. 44 is equivalent to the component model in FIG. 45. By visualizing a component model using the symbol illustrated in FIG. 43, the three-dimensional model in FIG. 44 can be converted into the component model in FIG. 45.

As described with reference to FIGS. 43 to 45, setting symbols that correspond to the elements defining multi-terminal capacitors facilitates editing circuit diagrams using circuit simulators, such as changing terminal arrangements. For example, a multi-terminal capacitor 1a with a terminal arrangement in three rows and three columns illustrated in FIG. 45 can be easily transformed into a multi-terminal capacitor 1b with a terminal arrangement in three rows and five columns illustrated in FIG. 46. FIG. 46 illustrates a multi-terminal capacitor with a terminal arrangement in three rows and five columns. The multi-terminal capacitor 1b illustrated in FIG. 46 includes fifteen terminals T1 to T15. In this example, the impedance of the symbol corresponding to the terminal T4 is equally or substantially equally divided between the symbol of the terminal T10 and the symbol of the terminal T13. The impedance of the symbol corresponding to the terminal T5 is equally or substantially equally divided between the symbol of the terminal T11 and the symbol of the terminal T14. The impedance of the symbol corresponding to the terminal T6 is equally or substantially equally divided between the symbol of the terminal T12 and the symbol of the terminal T15. As a result, the multi-terminal capacitor 1a with a terminal arrangement in three rows and three columns can be transformed into the multi-terminal capacitor 1b including a terminal arrangement in three rows and five columns.

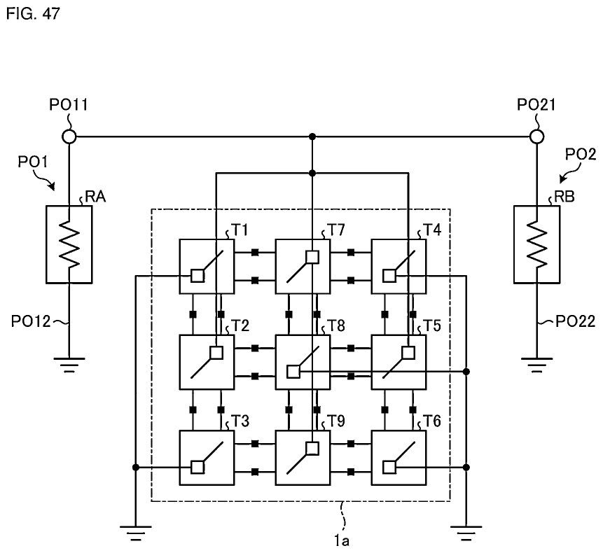

FIG. 47 illustrates an equivalent circuit of the substrate 10a including the multi-terminal capacitor 1 described with reference to FIG. 6. FIG. 47 shows the multi-terminal capacitor 1a using the symbols described with reference to FIG. 43. In the multi-terminal capacitor 1a in FIG. 47, the terminals T2, T5, T7, and T9 corresponding to four symbols for the positive pole are electrically coupled to the positive pole PO11 of the port PO1 and the positive pole PO21 of the port PO2. The terminals T1, T3, T4, T6, and T8 corresponding to five symbols for the negative pole are electrically coupled to a reference potential, for example, ground. The resistor RA is electrically coupled between the positive pole PO11 and the negative pole PO12. The resistor RB is electrically coupled between the positive pole PO21 and the negative pole PO22. With the connections as illustrated in FIG. 47, S parameters of the multi-terminal capacitor 1a can be obtained for impedance evaluation using a shunt-through method.

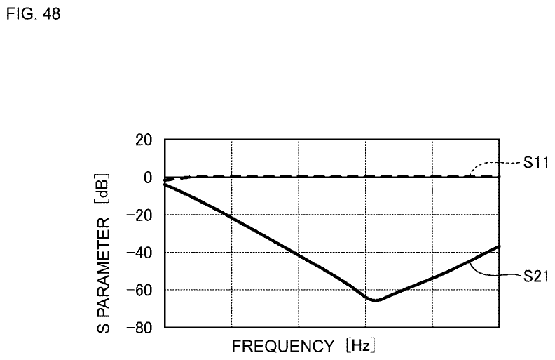

FIG. 48 illustrates an exemplary simulation result regarding S parameters. In FIG. 48, the horizontal axis represents frequency [Hz], and the vertical axis represents S parameter [dB]. FIG. 48 illustrates S11 and S21 among S parameters. S11 is equal or substantially equal to the value obtained by dividing the power reflected from the port PO1 by the power entering the port PO1. S21 is equal or substantially equal to the power gain when the impedance of the power supply and the load is about 50Ω.

### Application Example of Multi-Terminal Capacitor

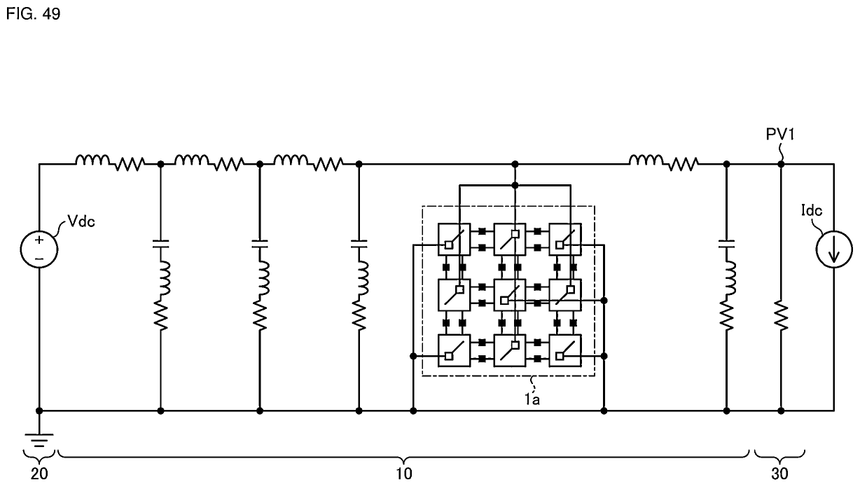

FIG. 49 illustrates an example of simulation in the time domain. In this example, power can be supplied from a direct-current (DC) power supply 20 to a load 30 via the substrate 10. A voltage Vdc from the DC power supply 20 can be supplied to the load 30 via the substrate 10. In this example, a current supply Idc is provided and coupled in parallel with the load 30. The connections of a resistive element and an inductive element and the connections of a resistive element, an inductive element, and a capacitive element in FIG. 49 represent the equivalent circuit of the substrate 10. The load 30 is, for example, a semiconductor chip such as a controller or processor, for example.

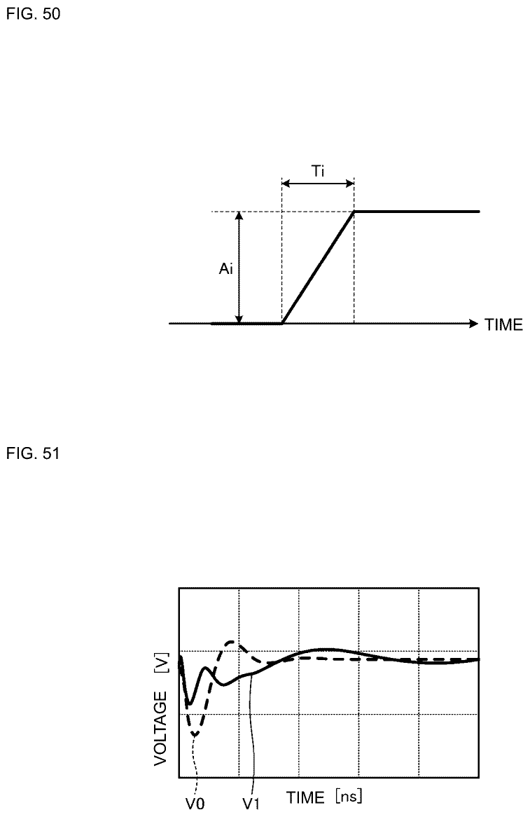

FIG. 50 illustrates the change in current from the current supply Idc in FIG. 49. In FIG. 50, the horizontal axis represents a time Ti spent for current rise, and the vertical axis represents an amplitude Ai.

FIG. 51 illustrates examples of the change in load voltage. In FIG. 51, the horizontal axis represents time [ns], and the vertical axis represents voltage [V]. The dashed line in FIG. 51 illustrates a voltage V0 when the multi-terminal capacitor 1a is not provided. The solid line in FIG. 51 illustrates a voltage V1 when the multi-terminal capacitor 1a is provided.

In FIGS. 49 to 51, in response to the operation of the load 30, the value of the current from the current supply Idc can increase, or the load voltage can decrease in certain situations. For example, as illustrated in FIG. 51, the load voltage first decreases and then starts to decrease in certain situations. In such a case, the variation in the load voltage can be reduced or prevented by charging or discharging the multi-terminal capacitor 1a provided at the substrate 10. As illustrated in FIG. 51, the voltage V1 when the multi-terminal capacitor 1a is provided varies less than the voltage V0 when the multi-terminal capacitor 1a is not provided.

### Simulation Device

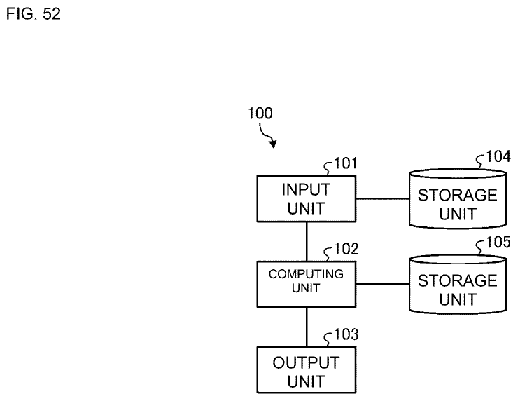

FIG. 52 illustrates an exemplary configuration of a simulation device according to the present invention. A simulation device 100 illustrated in FIG. 52 is provided with a program for calculating the characteristics of multi-terminal capacitors or the characteristics of circuits coupled with multi-terminal capacitors. In FIG. 52, the simulation device includes an input 101, a computer 102, an output 103, and storage 104 and 105.

The input 101 is operable to receive inputs of data regarding, for example, conditions for setting equivalent circuit models. The input 101 includes, for example, a keyboard and a mouse.

The computer 102 is operable to run a program using the data inputted through the input 101. The computer 102 includes, for example, a central processing unit (CPU).

The output 103 is operable to display, for example, computation results by obtained the computer 102 and characteristic waveforms obtained by a simulator. The output 103 may be, for example, a display device.

The storage 104 is operable to store data of equivalent circuit models. The data of equivalent circuit models stored by the storage 104 includes, for example, data of the multi-terminal capacitor 1a illustrated in FIG. 27, or data of the multi-terminal capacitor 1b illustrated in FIG. 28. The storage 105 is operable to store a program for executing a simulator. The simulator stored in the storage 105 is configured to calculate the characteristics of multi-terminal capacitors or the characteristics of circuits coupled with multi-terminal capacitors. The storage 104 and 105 may be provided by, for example, magnetic disk devices or semiconductor memories.

In FIG. 52, data inputted through the input 101 and data of equivalent circuit models can be stored in the storage 104. The computer 102 executes the program stored in the storage 105 and starts the simulator. The computer 102 performs computation using the simulator. The output 103 outputs characteristic waveforms obtained as a result of the computation by the computer 102 and other kinds of data in the form of, for example, graph.

The simulation device illustrated in FIG. 52 is provided with a program for calculating the characteristics of multi-terminal capacitors or the characteristics of circuits coupled with multi-terminal capacitors. By using the simulation device provided with the data of equivalent circuit models and program that can be used to calculate the characteristics of multi-terminal capacitors, circuit design of electronic devices using multi-terminal capacitors can be performed efficiently and accurately. This provides an efficient design environment for designers. Furthermore, by providing the simulation device that simplifies displaying and comparing the characteristics of multi-terminal capacitors, the efficiency of component selection tasks for designers can be improved. For example, the user can perform operations on a web page to design a desired multi-terminal capacitor. Subsequently, the S parameters of the multi-terminal capacitor can be measured. Accordingly, an equivalent circuit model that can achieve frequency characteristic waveforms of the S parameters can be created by selecting elements that match the waveforms and combining the selected elements. The created equivalent circuit model of the multi-terminal capacitor can then be used to calculate the characteristics of the multi-terminal capacitor or the characteristics of a circuit including the multi-terminal capacitor.

Overall, the simulation device illustrated in FIG. 52 is a device for calculating the characteristics of a multi-terminal capacitor or the characteristics of a circuit including the multi-terminal capacitor by using an equivalent circuit model of the multi-terminal capacitor created through the equivalent circuit model creation method described above. By using this simulation device, a simulation method can be provided. This simulation method calculates the characteristics of a multi-terminal capacitor or the characteristics of a circuit including the multi-terminal capacitor by using an equivalent circuit model of the multi-terminal capacitor created through the equivalent circuit model creation method described above. The characteristics of multi-terminal capacitors and the characteristics of circuits with multi-terminal capacitors, such as circuits coupled with multi-terminal capacitors, can be evaluated using various methods pertaining to different aspects such as the frequency domain and the time domain. By providing equivalent circuit models of various multi-terminal capacitors as a library, the characteristics of multi-terminal capacitors can be evaluated in a simulation environment specified by the user. By providing a dedicated simulation device, input operations such as model setting and output operations such as graph display can be easily performed, thereby enhancing user convenience.

### Equivalent Circuit Model Creation Program

A program for implementing the equivalent circuit model creation method described with reference to FIG. 1 may be created and run by a computer, for example. This program is an equivalent circuit model creation program for creating an equivalent circuit model of a multi-terminal capacitor having a configuration in which positive and negative outer electrode terminals are arranged in a staggered manner such that adjacent terminals among the positive and negative outer electrode terminals have different polarities. The equivalent circuit model creation program is configured to cause a computer to execute a process including a first step of measuring S parameters of the multi-terminal capacitor, a second step of deriving a total impedance of the multi-terminal capacitor based on S parameter measurement values measured in the first step, a third step of creating a two-terminal equivalent circuit model from the total impedance of the multi-terminal capacitor derived in the second step, a fourth step of deriving a unit-cell equivalent circuit model from the two-terminal equivalent circuit model created in the third step, a fifth step of creating a three-dimensional grid topology by combining the unit-cell equivalent circuit model derived in the fourth step and an equivalent circuit model of a parasitic component including capacitive and inductive circuit elements, and a sixth step of setting terminals of the multi-terminal capacitor at nodes in the three-dimensional grid topology created in the fifth step. This equivalent circuit model creation program can be stored in, for example, the storage 105 in FIG. 52. This equivalent circuit model creation program can be, for example, read from the storage 105 and executed by the computer 102 in FIG. 52. This equivalent circuit model creation program may be stored in a storage medium detachable from the computer. For example, the equivalent circuit model creation program may be stored in a Universal Serial Bus (USB) flash drive.

According to the above-described method, equivalent circuit models of multi-terminal capacitors with outer electrode terminals arranged in a grid can be provided. Positive and negative rows of outer electrode terminals may be alternately arranged in parallel, defining a striped arrangement. The impedance of a multi-terminal capacitor can be derived from S parameter measurement values measured using a mounting installation involving a substrate including two ports. Because the measurement method using two ports instead of multiple ports is used, the man-hours of measurement evaluation can be reduced.

A two-terminal equivalent circuit model can be provided by the fitting process, based on the derived total impedance. The impedance of a unit cell can be derived from the total impedance, while the specific periodic structure of a grid equivalent circuit model is taken into account. A two-dimensional grid topology can be created by combining a unit-cell equivalent circuit model and a wire equivalent circuit model as circuit elements. By setting terminals at the nodes in the grid, an overall equivalent circuit model can be provided. As such, an equivalent circuit model with a topology corresponding to a multi-terminal capacitor structure can be provided. Repeatedly using the characteristics of a unit cell reduces the amount of calculation in circuit simulation. Furthermore, a SPICE model with high accuracy and low computational cost can be provided for both of the time and frequency domains.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An equivalent circuit model creation method for creating an equivalent circuit model of a multi-terminal capacitor including positive and negative outer electrode terminals arranged in a staggered manner such that adjacent terminals among the positive and negative outer electrode terminals have different polarities, the equivalent circuit model creation method comprising:
measuring scattering parameters (S parameters) of the multi-terminal capacitor;
deriving a total impedance of the multi-terminal capacitor based on S parameter measurement values measured in the measuring the scattering parameters;
creating a two-terminal equivalent circuit model from the total impedance of the multi-terminal capacitor derived in the deriving the total impedance of the multi-terminal capacitor;
deriving a unit-cell equivalent circuit model from the two-terminal equivalent circuit model created in the creating the two-terminal equivalent circuit model;
creating a three-dimensional grid topology by combining the unit-cell equivalent circuit model derived in the deriving the unit-cell equivalent circuit model and an equivalent circuit model of a parasitic component including capacitive and inductive circuit elements; and
setting terminals of the multi-terminal capacitor at nodes in the three-dimensional grid topology created in the creating the three-dimensional grid topology.

2. The equivalent circuit model creation method according to claim 1, wherein, in the creating the two-terminal equivalent circuit model, the two-terminal equivalent circuit model is created through a fitting process of adjusting simulation values to approximate to the S parameter measurement values.

3. The equivalent circuit model creation method according to claim 2, wherein, in the fitting process, the two-terminal equivalent circuit model is created by progressively coupling circuit elements to match the S parameter measurement values.

4. The equivalent circuit model creation method according to claim 1, wherein, in the deriving the unit-cell equivalent circuit model, for division into K unit cells coupled in a matrix, a resistance and an inductance are multiplied by K, a capacitance is multiplied by 1/K, and the resistance, the inductance, and the capacitance are assigned to each unit cell.

5. The equivalent circuit model creation method according to claim 4, wherein, in the deriving the unit-cell equivalent circuit model, the impedance of each cell of the K unit cells coupled in a matrix is multiplied by a weighting coefficient corresponding to a location of the unit cell in the matrix.

6. The equivalent circuit model creation method according to claim 5, wherein, in the deriving the unit-cell equivalent circuit model, when the unit cell is positioned at a periphery of the matrix, and the unit cell corresponds to an extended portion of an electrode, a weighting coefficient is set with the extended portion taken into account.

7. The equivalent circuit model creation method according to claim 1, wherein, in the measuring the scattering parameters, the S parameters are measured using a jig that includes a substrate including the multi-terminal capacitor.

8. A non-transitory computer-readable medium including an equivalent circuit model creation program for creating an equivalent circuit model of a multi-terminal capacitor including positive and negative outer electrode terminals arranged in a staggered manner such that adjacent terminals among the positive and negative outer electrode terminals have different polarities, the equivalent circuit model creation program causing a computer to execute a process comprising:
measuring scattering parameters (S parameters) of the multi-terminal capacitor;
deriving a total impedance of the multi-terminal capacitor based on S parameter measurement values measured in the measuring the scattering parameters;
creating a two-terminal equivalent circuit model from the total impedance of the multi-terminal capacitor derived in the deriving the total impedance of the multi-terminal capacitor;
deriving a unit-cell equivalent circuit model from the two-terminal equivalent circuit model created in the creating the two-terminal equivalent circuit model;
creating a three-dimensional grid topology by combining the unit-cell equivalent circuit model derived in the deriving the unit-cell equivalent circuit model and an equivalent circuit model of a parasitic component including capacitive and inductive circuit elements; and
setting terminals of the multi-terminal capacitor at nodes in the three-dimensional grid topology created in the creating the three-dimensional grid topology.

9. The non-transitory computer-readable medium according to claim 8, wherein, in the creating the two-terminal equivalent circuit model, the two-terminal equivalent circuit model is created through a fitting process of adjusting simulation values to approximate to the S parameter measurement values.

10. The non-transitory computer-readable medium according to claim 9, wherein, in the fitting process, the two-terminal equivalent circuit model is created by progressively coupling circuit elements to match the S parameter measurement values.

11. The non-transitory computer-readable medium according to claim 8, wherein, in the deriving the unit-cell equivalent circuit model, for division into K unit cells coupled in a matrix, a resistance and an inductance are multiplied by K, a capacitance is multiplied by 1/K, and the resistance, the inductance, and the capacitance are assigned to each unit cell.

12. The non-transitory computer-readable medium according to claim 11, wherein, in the deriving the unit-cell equivalent circuit model, the impedance of each cell of the K unit cells coupled in a matrix is multiplied by a weighting coefficient corresponding to a location of the unit cell in the matrix.

13. The non-transitory computer-readable medium according to claim 12, wherein, in the deriving the unit-cell equivalent circuit model, when the unit cell is positioned at a periphery of the matrix, and the unit cell corresponds to an extended portion of an electrode, a weighting coefficient is set with the extended portion taken into account.

14. The non-transitory computer-readable medium according to claim 13, wherein, in the measuring the scattering parameters, the S parameters are measured using a jig that includes a substrate including the multi-terminal capacitor.

15. A simulation method for calculating characteristics of a multi-terminal capacitor or characteristics of a circuit including the multi-terminal capacitor by using an equivalent circuit model of the multi-terminal capacitor created through the equivalent circuit model creation method according to claim 1.

16. A simulation device for calculating characteristics of a multi-terminal capacitor or characteristics of a circuit including the multi-terminal capacitor by using an equivalent circuit model of the multi-terminal capacitor created through the equivalent circuit model creation method according to claim 1.
